(19) United States
(12) Patent Application Publication
(10) Pub. No.: US 2025/0324591 A1
(43) Pub. Date: Oct. 16, 2025

(54) MEMORY DEVICE AND METHOD OF FABRICATING THE SAME

(71) Applicant: MACRONIX International Co., Ltd., Hsinchu (TW)

(72) Inventor: Yuan-Chieh Chiu, Hsinchu County (TW)

(73) Assignee: MACRONIX International Co., Ltd., Hsinchu (TW)

(21) Appl. No.: 18/636,275

(22) Filed: Apr. 16, 2024

(51) Int. Cl. H10B 43/27; H10B 41/27

(52) U.S. Cl. CPC H10B 43/27; H10B 41/27

(57) ABSTRACT

A memory device includes a stacked structure, a channel pillar, a charge storage structure, and a separation wall. The stacked structure is located above a substrate and includes conductive layers and insulating layers arranged alternately with each other. The channel pillar passes through the stacked structure. The charge storage structure is located between the channel pillar and the conductive layer. The separation wall passes through the stacked structure, the separation wall including sub-walls stacked on each other. Of two adjacent sub-walls among the sub-walls, an upper width of a lower sub-wall is greater than a lower width of an upper sub-wall. The memory device can be applied to 3D NAND flash memory to create memory devices with high capacity and performance.

### BACKGROUND

### Technical Field

The embodiments of the disclosure relate to a semiconductor device and a method of fabricating the same, and particularly, to a memory device and a method of fabricating the same.

### Related Art

A non-volatile memory has the advantage that stored data does not disappear at power-off, so it becomes widely used for a personal computer or other electronic equipment. Currently, the three-dimensional (3D) memory commonly used in the industry includes a NOR memory and a NAND memory. In addition, another type of 3D memory is an AND memory, which can be applied to a multi-dimensional memory array with high integration and high area utilization, and has an advantage of a high operation speed. Therefore, the development of a 3D memory device has gradually become the current trend.

### SUMMARY

The embodiments of the disclosure provide a memory device and a method of fabricating the same capable of reducing the aspect ratio of holes or trenches when performing etching processes to reduce the difficulty in the etching processes.

An embodiment of the disclosure provides a memory device including a stacked structure, a channel pillar, a charge storage structure, and a separation wall. The stacked structure is located above a dielectric substrate and includes a plurality of conductive layers and a plurality of insulating layers arranged alternately with each other. The channel pillar passes through the stacked structure. The charge storage structure is located between the channel pillar and the conductive layer. The separation wall passes through the stacked structure, and the separation wall includes a plurality of sub-walls stacked on each other. Of two adjacent sub-walls among the plurality of sub-walls of the separation wall, an upper width of a lower sub-wall is greater than a lower width of an upper sub-wall.

An embodiment of the disclosure provides a memory device including a staircase structure, a dielectric layer, and a support pillar. The staircase structure is located above a dielectric substrate and includes a plurality of conductive layers and a plurality of insulating layers arranged alternately with each other. The dielectric layer is covered on the staircase structure. The support pillar passes through the staircase structure and the dielectric layer. The support pillar includes a plurality of sub-pillars stacked on each other. Of two adjacent sub-pillars among the plurality of sub-pillars of the support pillar, an upper width of a lower sub-pillar is greater than a lower width of an upper sub-pillar.

An embodiment of the disclosure provides a method of fabricating a memory device including steps below. A stacked structure is formed above a substrate, the stacked structure including a plurality of conductive layers and a plurality of insulating layers arranged alternately with each other. A channel pillar is formed in the stacked structure. A charge storage structure is formed between the channel pillar and the conductive layer. A separation wall is formed to pass through the stacked structure, the separation wall including a plurality of sub-walls stacked on each other. Of two adjacent sub-walls among the plurality of sub-walls of the separation wall, an upper width of a lower sub-wall is greater than a lower width of an upper sub-wall. A support pillar is formed to pass through a staircase structure of the stacked structure and a dielectric layer on the staircase structure. The support pillar includes a plurality of sub-pillars stacked on each other. Of two adjacent sub-pillars among the plurality of sub-pillars of the support pillar, an upper width of a lower sub-pillar is greater than a lower width of an upper sub-pillar.

Thus, the method of fabricating a memory device according to the embodiments of the disclosure can be integrated with existing processes and can reduce the aspect ratio of holes or trenches when performing etching processes to reduce the difficulty in the etching processes and avoid abnormal communication resulting from inclination of holes or trenches.

### BRIEF DESCRIPTION OF DRAWINGS

FIG. 1A to FIG. 1L are schematic cross-sectional views of a fabrication process of a memory device according to an embodiment of the disclosure.

FIG. 2A to FIG. 2L are schematic cross-sectional views of a fabrication process of another memory device according to an embodiment of the disclosure.

FIG. 3 is a top view of a memory device according to an embodiment of the disclosure.

FIG. 4A to FIG. 4D respectively show schematic enlarged views of channel pillars in FIG. 1L and FIG. 2L.

FIG. 5A and FIG. 5B respectively show schematic enlarged views of separation walls in FIG. 1L and FIG. 2L.

FIG. 6A and FIG. 6B respectively show schematic enlarged views of a support pillar in FIG. 2L.

FIG. 7A to FIG. 7C are schematic cross-sectional views of combined structures.

### DESCRIPTION OF EMBODIMENTS

As the number of gate layers continues to increase, the aspect ratio of holes or slit trenches extending through a stacked structure becomes larger, which increases the difficulty in etching. In the embodiments of the disclosure, channel pillars, support pillars, and separation walls are respectively formed by a plurality of sacrificial pillars and sacrificial walls to reduce the aspect ratio of holes or slit trenches formed in each portion and thereby reduce the difficulty in the etching process and suppress issues resulting from etching variations.

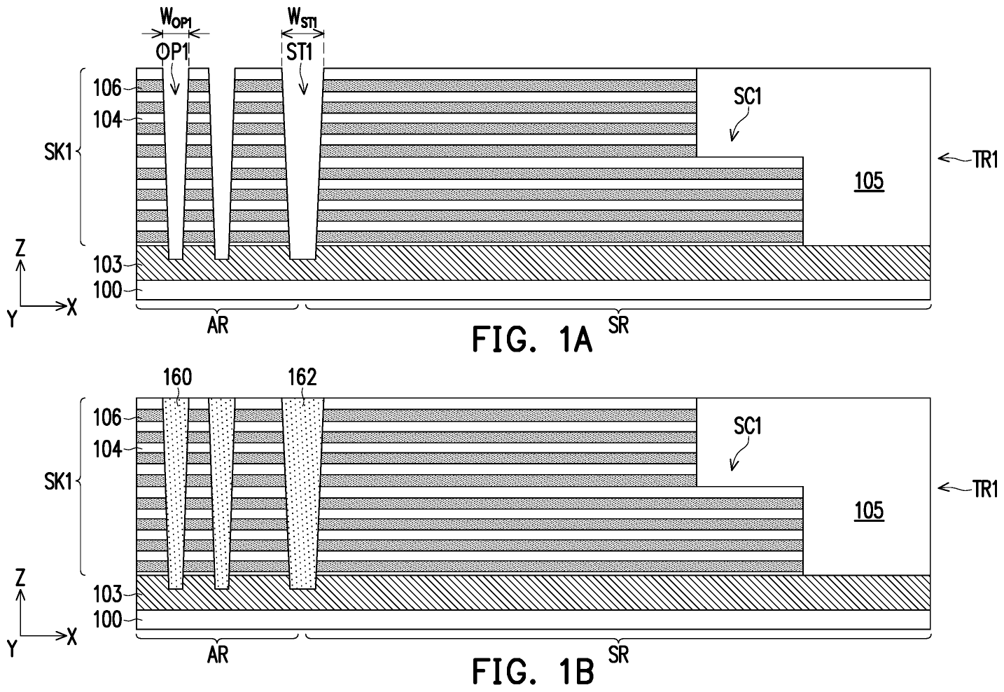

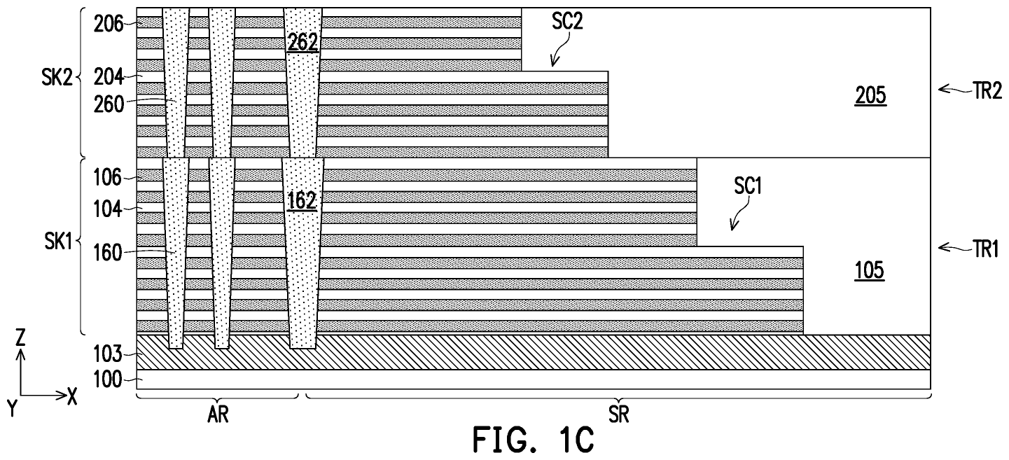

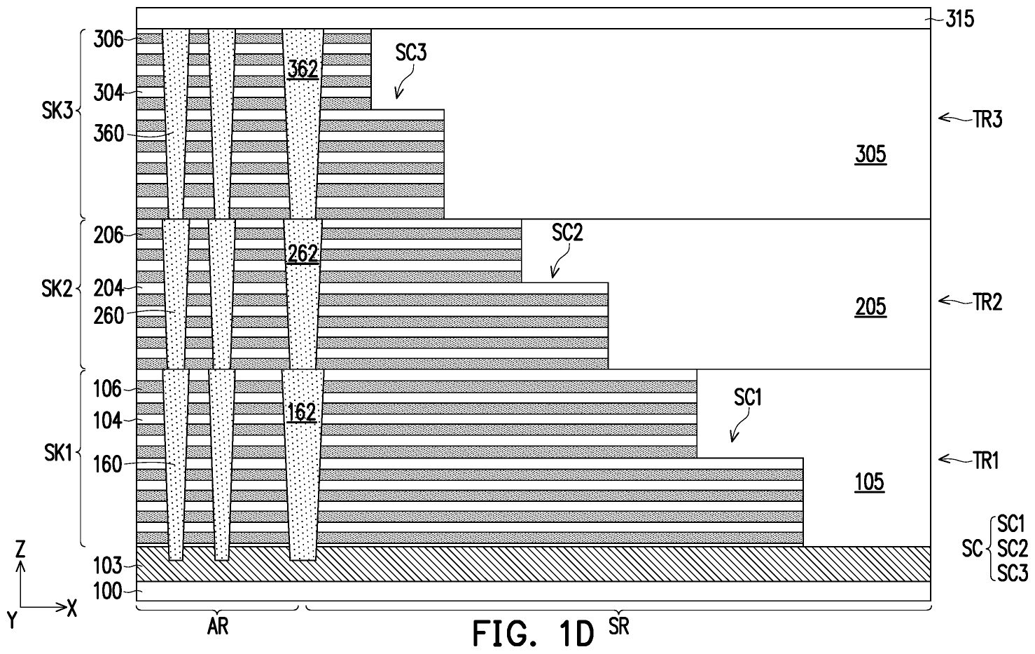

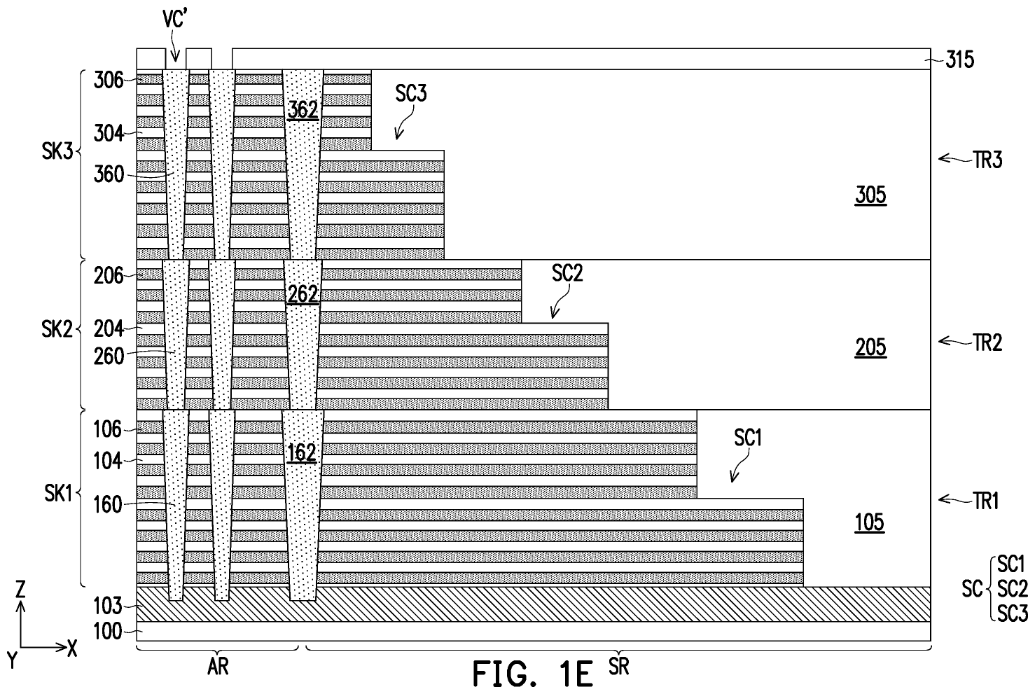

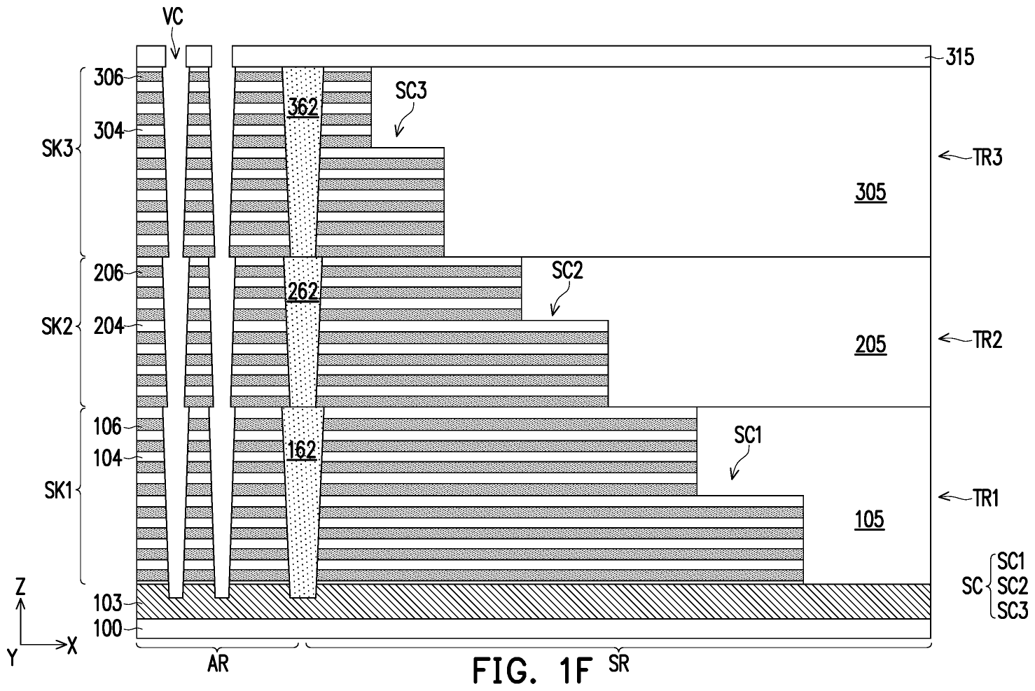

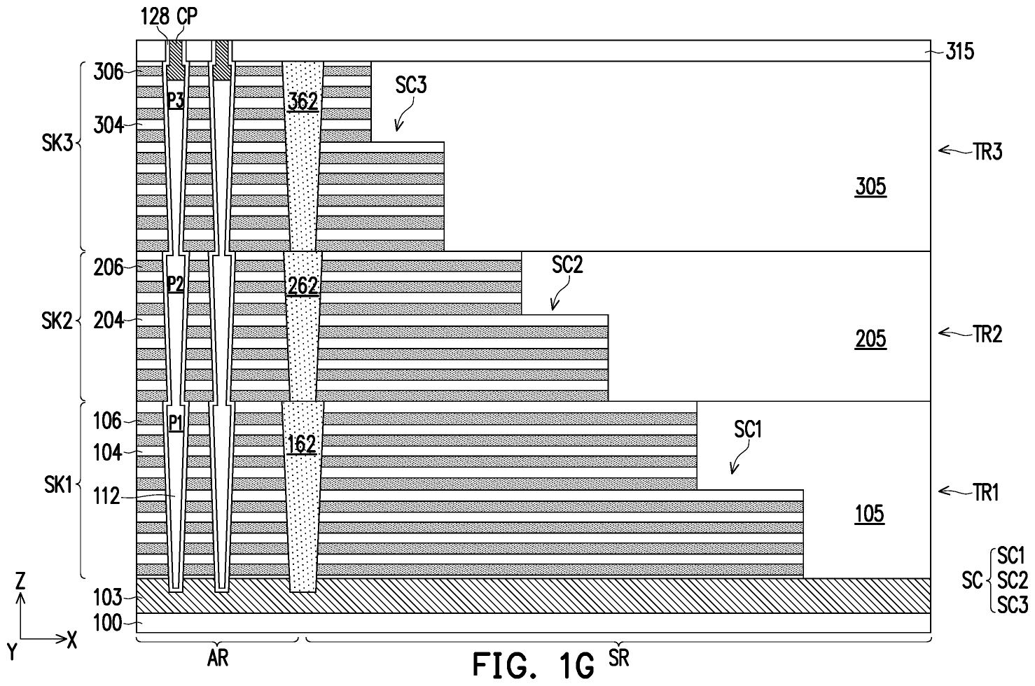

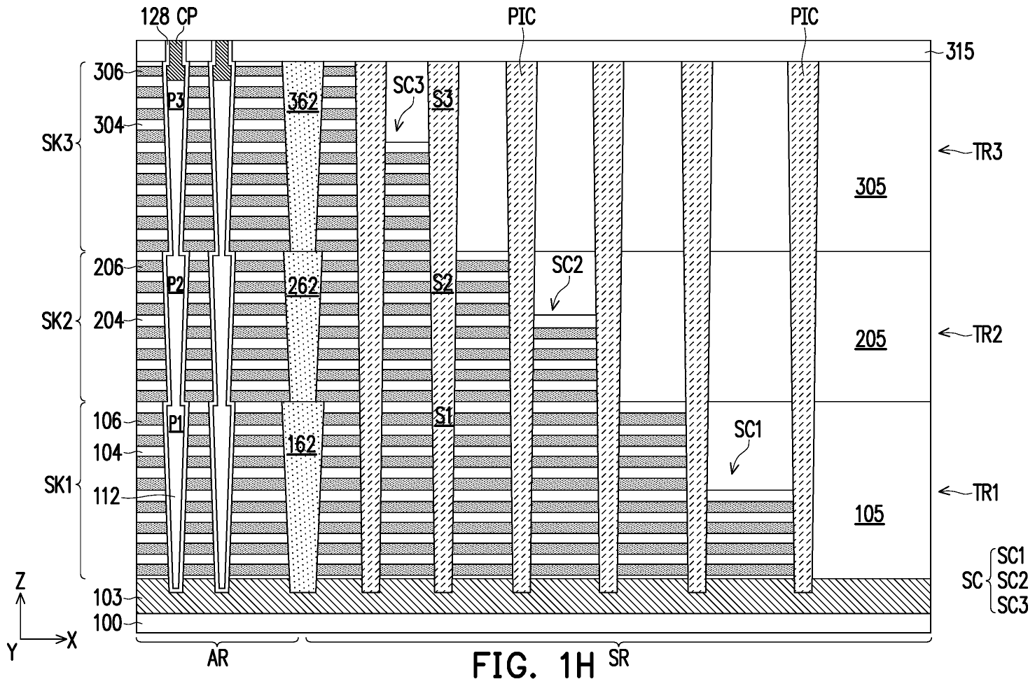

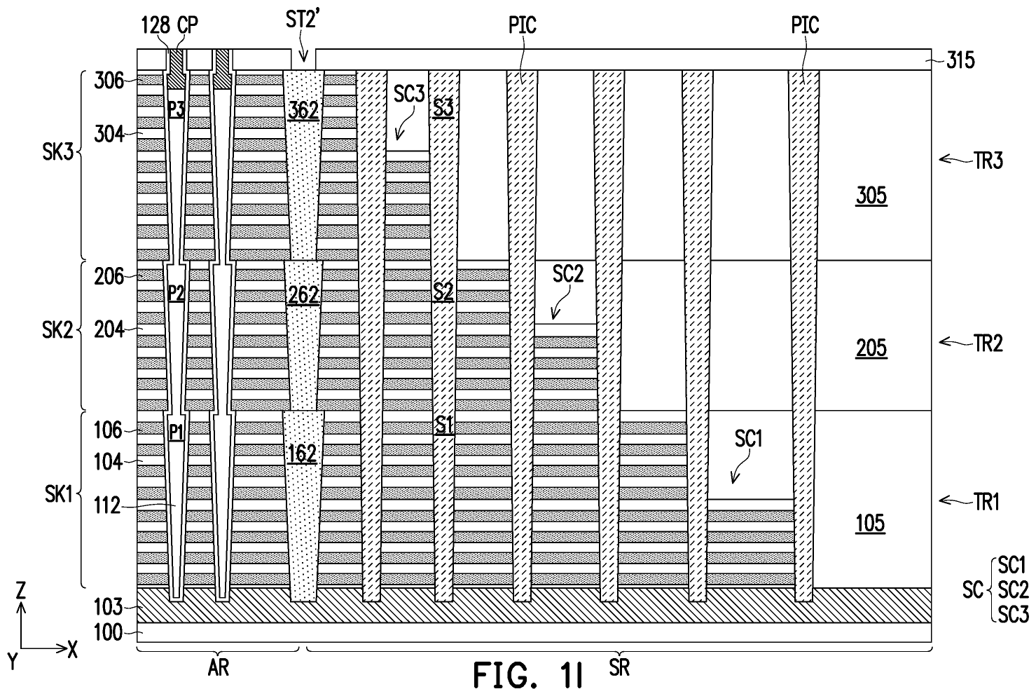

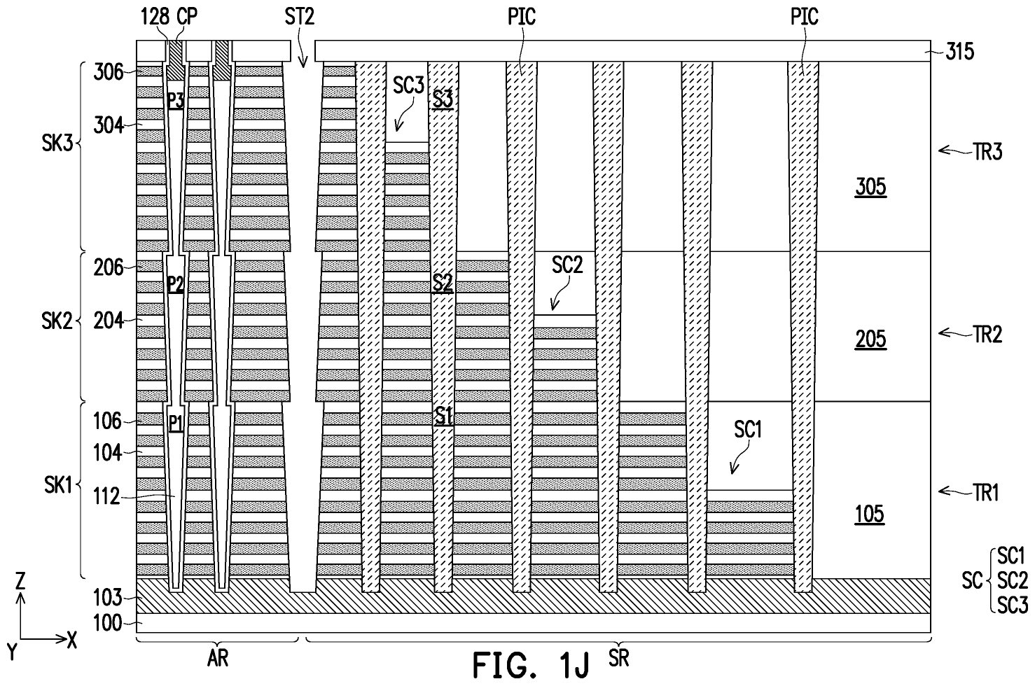

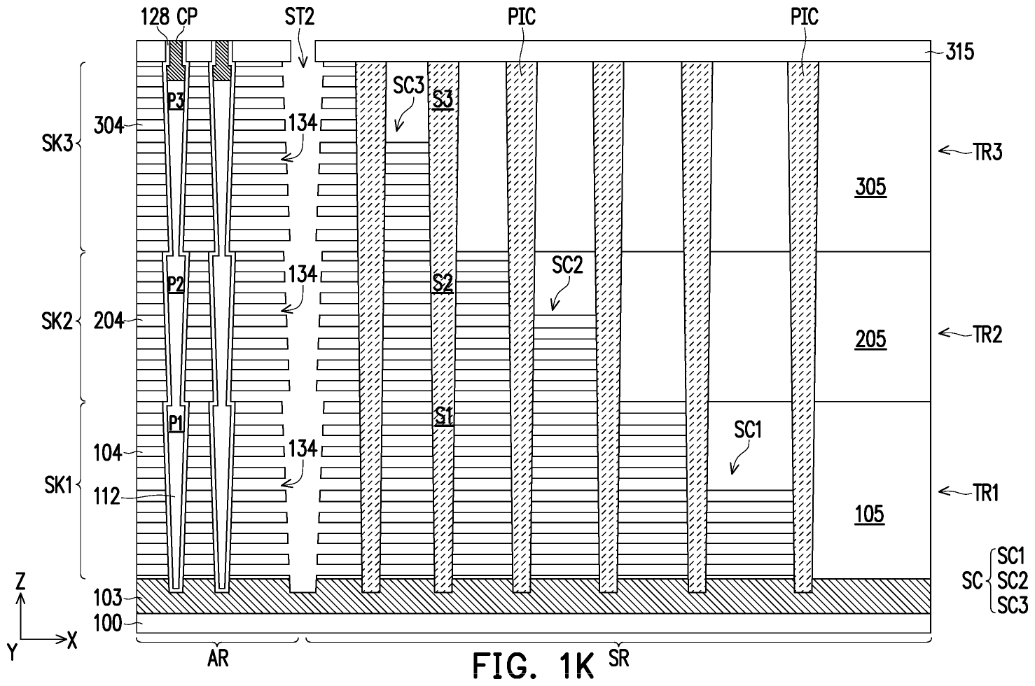

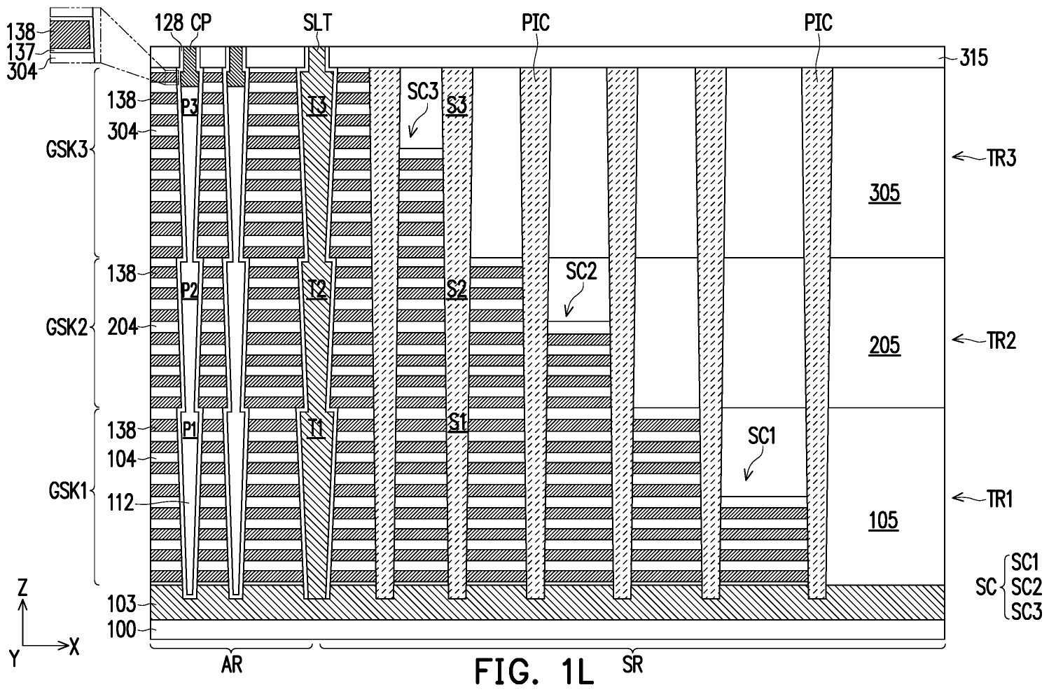

FIG. 1A to FIG. 1L are schematic cross-sectional views of a fabrication process of a memory device according to an embodiment of the disclosure.

Referring to FIG. 1A, a substrate 100 is provided. The substrate 100 includes an array region AR and a staircase region SR. The substrate 100 includes semiconductor such as silicon. A metal interconnect structure and a dielectric layer above the metal interconnect structure may be provided on the substrate 100. First, a semiconductor layer 103 is formed on the substrate 100. The semiconductor layer 103 is, for example, a grounded polysilicon layer. The semiconductor layer 103 may also be referred to as a dummy gate, which may serve to turn off a leakage path. A stacked structure SK1 is formed on the semiconductor layer 103. The stacked structure SK1 may also be referred to as an insulating stacked structure SK1. In this embodiment, the stacked structure SK1 is composed of insulating layers 104 and intermediate layers 106 sequentially stacked alternately with each other on the substrate 100. The insulating layer 104 is, for example, a silicon oxide layer. The intermediate layer 106 is, for example, a silicon nitride layer. The intermediate layer 106 may serve as a sacrificial layer to be partially removed in subsequent processes.

Next, the stacked structure SK1 is patterned to form a staircase structure SC1 in the staircase region SR. Subsequently, a dielectric layer 105 is formed on the staircase structure SC1. The material of the dielectric layer 105 is, for example, silicon oxide. The dielectric layer 105 may be planarized by a planarization process such as a chemical-mechanical polishing process.

Next, referring to FIG. 1A, a plurality of openings OP1 and a slit trench ST1 are formed in the array region AR of the stacked structure SK1. The openings OP1 and the slit trench ST1 extend from the stacked structure SK1 to the semiconductor layer 103. In this embodiment, in a top view, the opening OP1 and the slit trench ST1 have profiles and dimensions different from each other. the opening OP1 has a circular profile (not shown), but the disclosure is not limited thereto. The slit trench ST1 has a strip shape (not shown). A width W_{ST1} of the slit trench ST1 is greater than a diameter Wₒₚ₁ of the opening OP1. Since the width W_{ST1} of the slit trench ST1 is greater than the diameter Wₒₚ₁ of the opening OP1, the etching rate for forming the slit trench ST1 is greater than the etching rate for forming the opening OP1. Therefore, the depth of the slit trench ST1 in the semiconductor layer 103 is greater than the depth of the opening OP1 in the semiconductor layer 103. In some embodiments, the upper width of the opening OP1 is greater than the lower width thereof, and the cross-section of the opening OP1 has, for example, a conical shape. Similarly, the upper width of the slit trench ST1 is greater than the lower width thereof, and the cross-section of the slit trench ST1 has, for example, a conical shape. In the fabrication process, by controlling the number of layers, the photolithography, and the etching process of the intermediate layers 106 and the insulating layers 104 of the stacked structure SK1, the opening OP1 and the slit trench ST1 may have the required profiles and shapes, and a sufficient distance may be provided between the opening OP1 and the slit trench ST1. Thus, it is possible to avoid the difficulty in control of the etching plasma resulting from an excessive depth, which may otherwise cause the slit trench to tilt or shift, cause formation of a notch in the opening OP1, and lead to abnormal communication between the opening OP1 and the slit trench ST1.

Referring to FIG. 1B, a sacrificial material is formed on the stacked structure SK1 and in the openings OP1 and the slit trench ST1. Subsequently, an etch-back process or a chemical-mechanical polishing process is performed to remove the excess sacrificial material on the stacked structure SK1 to form a plurality of sacrificial pillars 160 and a sacrificial wall 162 respectively in the plurality of openings OP1 and the slit trench ST1. The materials of the sacrificial pillar 160 and the sacrificial wall 162 are different from the insulating layer 104 and are different from the intermediate layer 106. The sacrificial pillar 160 and the sacrificial wall 162 are, for example, amorphous silicon or carbon-containing organic materials. The carbon-containing organic material may be a polymer such as a photoresist. The photoresist may be a positive photoresist or a negative photoresist. The materials of the sacrificial pillar 160 and the sacrificial wall 162 are not limited thereto, and other materials such as polysilicon or tungsten may also be used. The sacrificial pillar 160 has a circular profile (not shown). The sacrificial wall 162 has a strip shape (not shown). In some embodiments, the upper width of the sacrificial pillar 160 is greater than the lower width thereof, and the cross-section of the sacrificial pillar 160 has, for example, a conical shape. Similarly, the upper width of the sacrificial wall 162 is greater than the lower width thereof, and the cross-section of the sacrificial wall 162 has, for example, a conical shape. At this time, a first tier TR1 has been formed.

Referring to FIG. 1C, a stacked structure SK2 is formed on the stacked structure SK1. In this embodiment, the stacked structure SK2 may be composed of insulating layers 204 and intermediate layers 206 sequentially stacked alternately with each other. The materials of the insulating layer 204 and the intermediate layer 206 may be the same as or similar to the insulating layer 104 and the intermediate layer 106, respectively. Then, according to the above method, the stacked structure SK2 is patterned to form a staircase structure SC2 in the staircase region SR. Subsequently, a dielectric layer 205 is formed on the staircase structure SC2.

Subsequently, according to the above method, a plurality of sacrificial pillars 260 and a sacrificial wall 262 are formed in the stacked structure SK2. In the fabrication process, the number of layers, the photolithography, and the etching process of the intermediate layers 206 and the insulating layers 204 of the stacked structure SK2 may be controlled such that the formed sacrificial pillar 260 lands on the sacrificial pillar 160 and the formed sacrificial wall 262 lands on the sacrificial wall 162. The sacrificial pillar 260 has a circular profile (not shown). The sacrificial wall 262 has a strip shape (not shown). In some embodiments, the upper width of the sacrificial pillar 260 is greater than the lower width thereof, and the cross-section of the sacrificial pillar 260 has, for example, a conical shape. Similarly, the upper width of the sacrificial wall 262 is greater than the lower width thereof, and the cross-section of the sacrificial wall 262 has, for example, a conical shape. At this time, a second tier TR2 is formed.

Referring to FIG. 1D, a stacked structure SK3 is formed on the stacked structure SK2. In this embodiment, the stacked structure SK3 may be composed of insulating layers 304 and intermediate layer 306 sequentially stacked alternately with each other. The materials of the insulating layer 304 and the intermediate layer 306 may be the same as or similar to the insulating layer 104 and the intermediate layer 106, respectively. Then, according to the above method, the stacked structure SK3 is patterned to form a staircase structure SC3 in the staircase region SR. Subsequently, a dielectric layer 305 is formed on the staircase structure SC3. The staircase structures SC1, SC2, and SC3 may be collectively referred to as a staircase structure SC.

Subsequently, according to the above method, sacrificial pillars 360 and a sacrificial wall 362 are formed in the stacked structure SK3. The sacrificial pillar 360 lands on the sacrificial pillar 260, and the sacrificial wall 362 lands on the sacrificial wall 262. Similarly, the sacrificial pillar 360 has a circular profile (not shown). The sacrificial wall 362 has a strip shape (not shown). In some embodiments, the upper width of the sacrificial pillar 360 is greater than the lower width thereof, and the cross-section of the sacrificial pillar 360 has, for example, a conical shape. Similarly, the upper width of the sacrificial wall 362 is greater than the lower width thereof, and the cross-section of the sacrificial wall 362 has, for example, a conical shape.

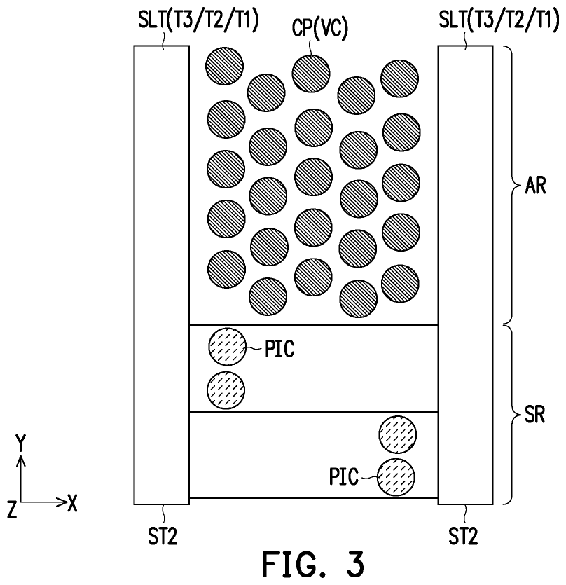

The lower width of the sacrificial pillar 360 is smaller than the upper width of the sacrificial pillar 260, and the lower width of the sacrificial pillar 260 is smaller than the upper width of the sacrificial pillar 160. The lower width of the sacrificial wall 362 is smaller than the upper width of the sacrificial wall 262, and the lower width of the sacrificial wall 262 is smaller than the upper width of the sacrificial wall 162. At this time, a third tier TR3 has been formed. The sacrificial pillars 360, 260, and 160 will be subsequently replaced to form channel pillars CP. The sacrificial walls 362, 262, 162 will be subsequently replaced to form separation walls SLT, as shown in FIG. 3. In FIG. 3, the channel pillar CP extends in a direction Z, and the separation wall SLT has a strip shape extending in a direction Y and the direction Z. Thus, according to the channel pillar CP and the separation wall SLT in the top view of FIG. 3, it is learned that the profiles of the sacrificial pillar 360 and the sacrificial wall 362 are respectively circular and strip-shaped in the top view.

Subsequently, a cap insulating layer 315 is formed on the stacked structure SK3. The material of the cap insulating layer 315 is, for example, silicon oxide. The cap insulating layer 315 may be planarized by a planarization process such as a chemical-mechanical polishing process.

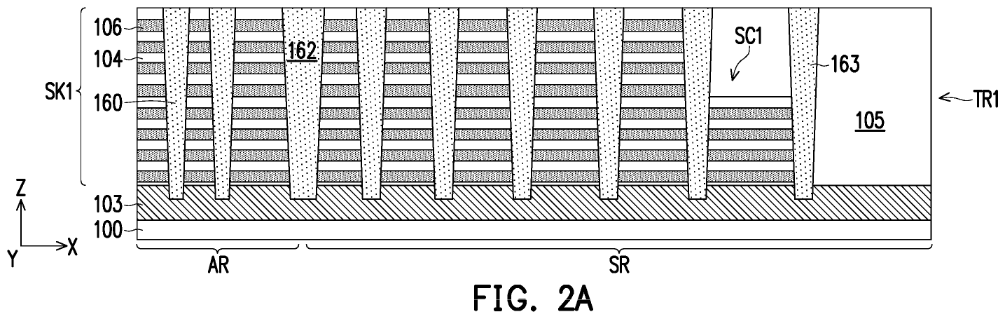

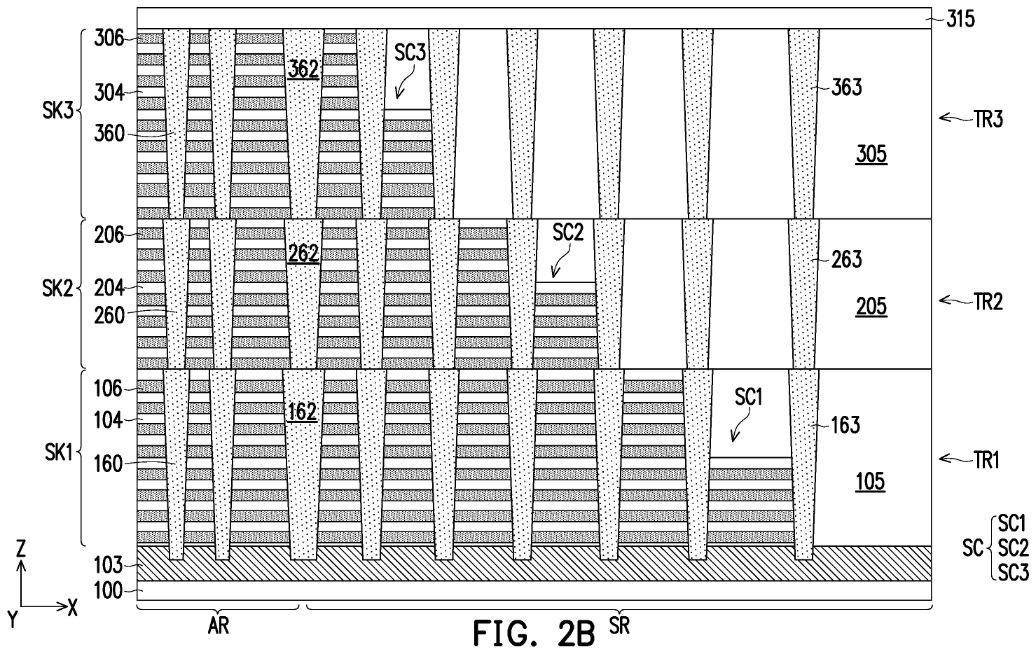

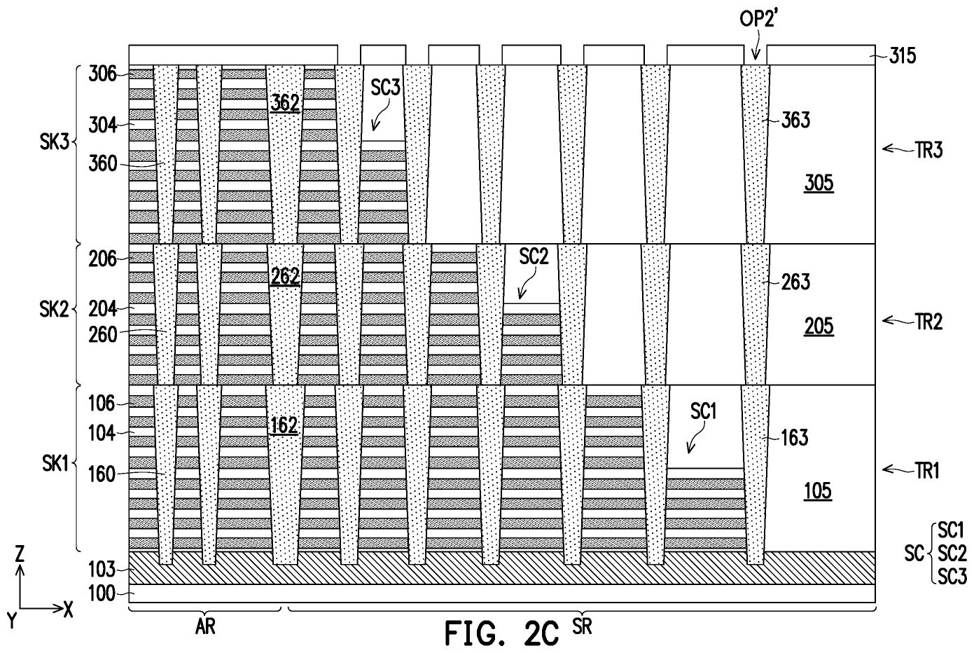

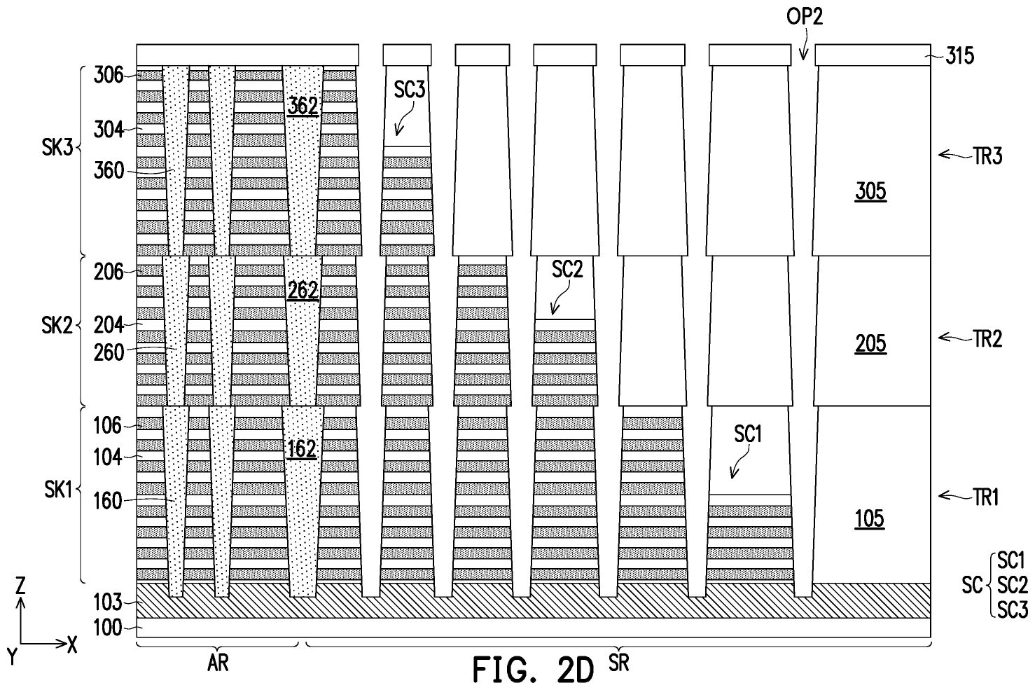

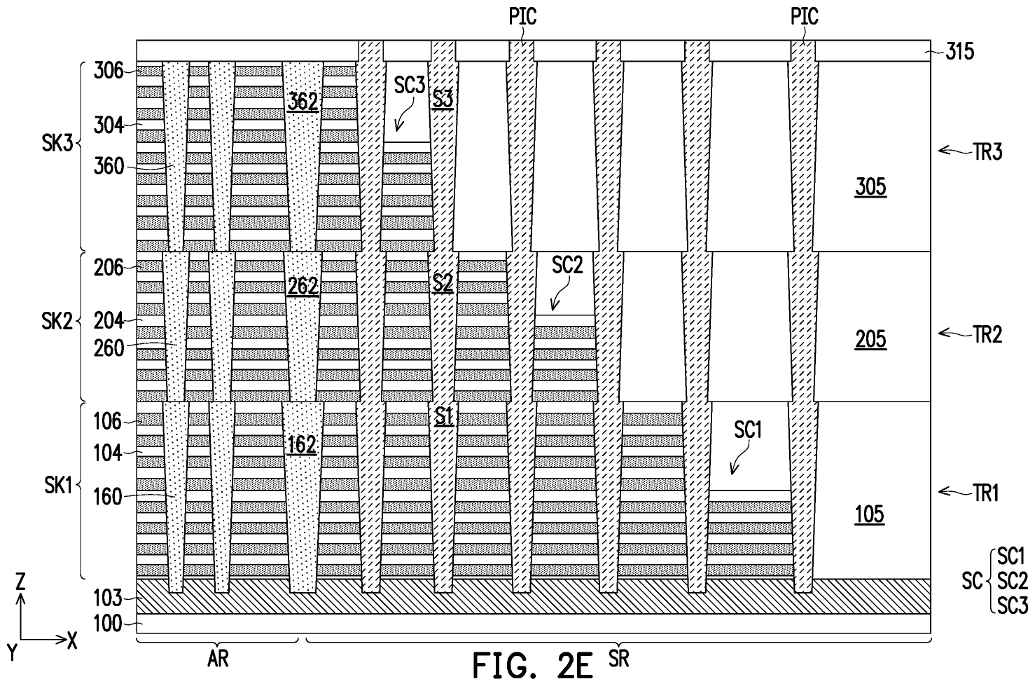

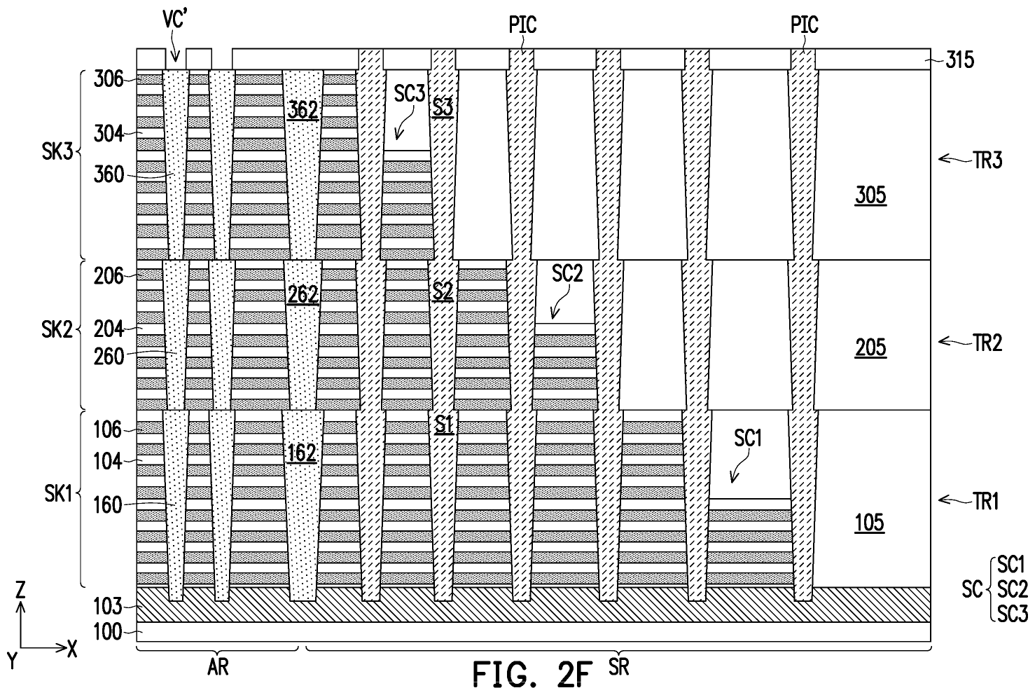

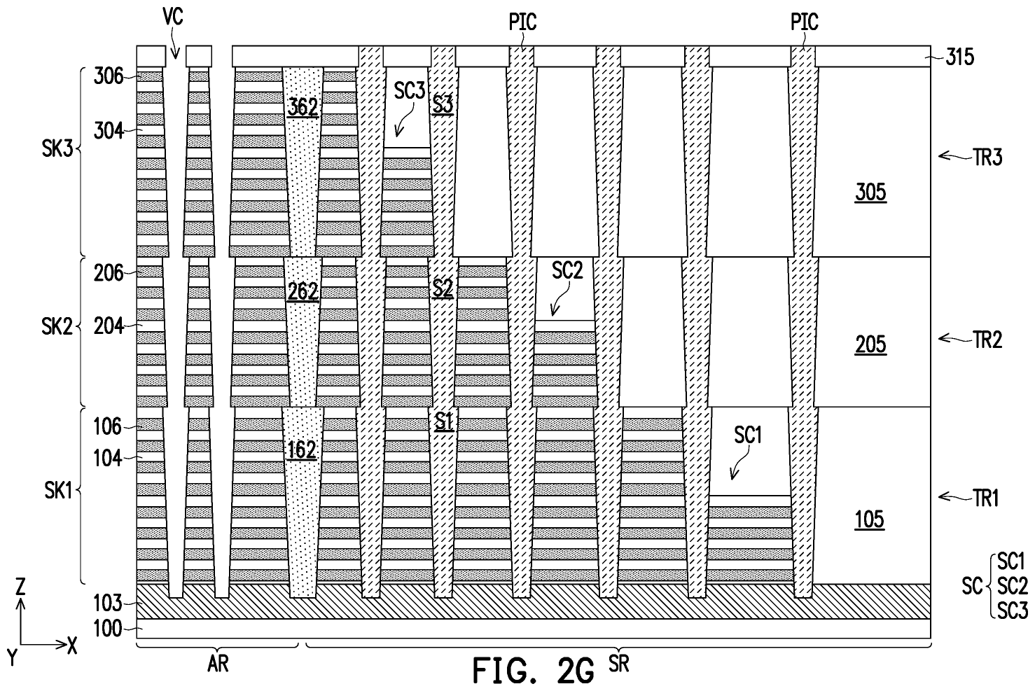

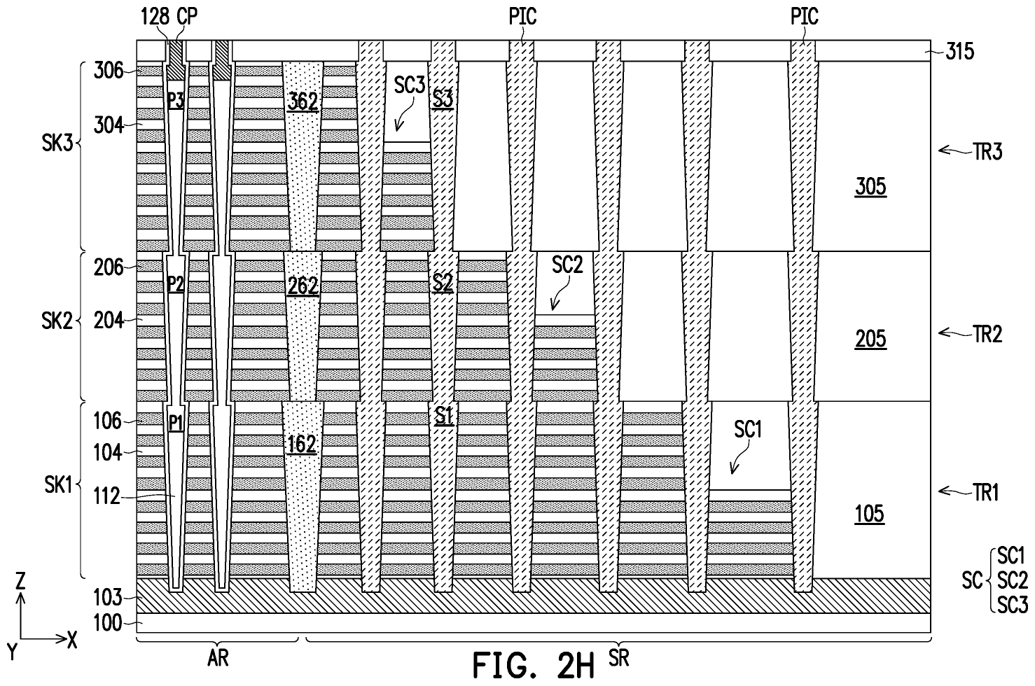

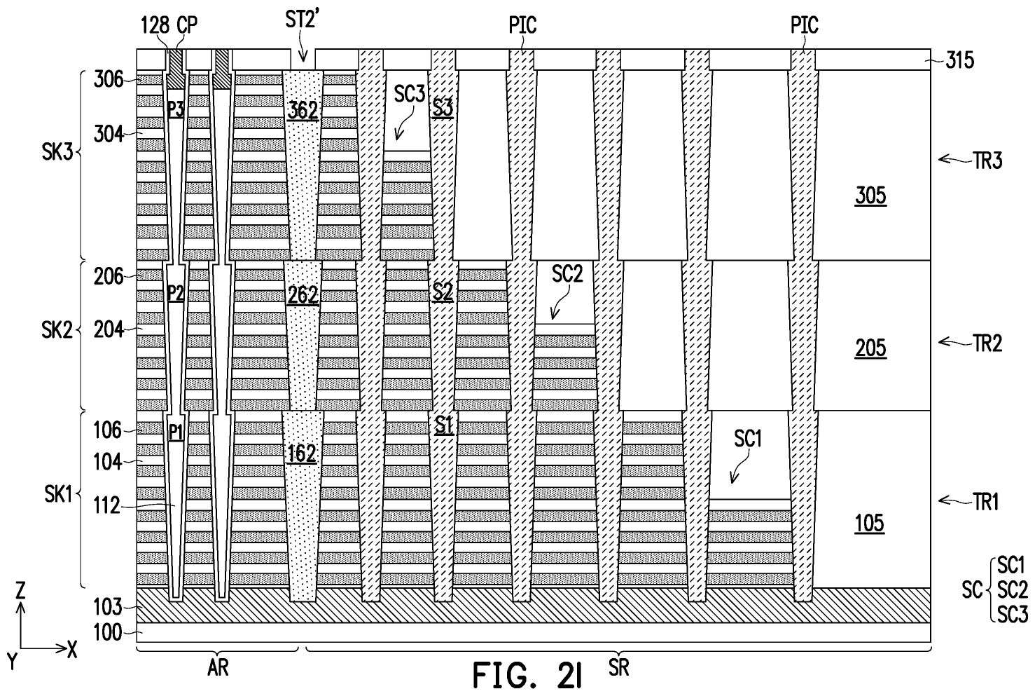

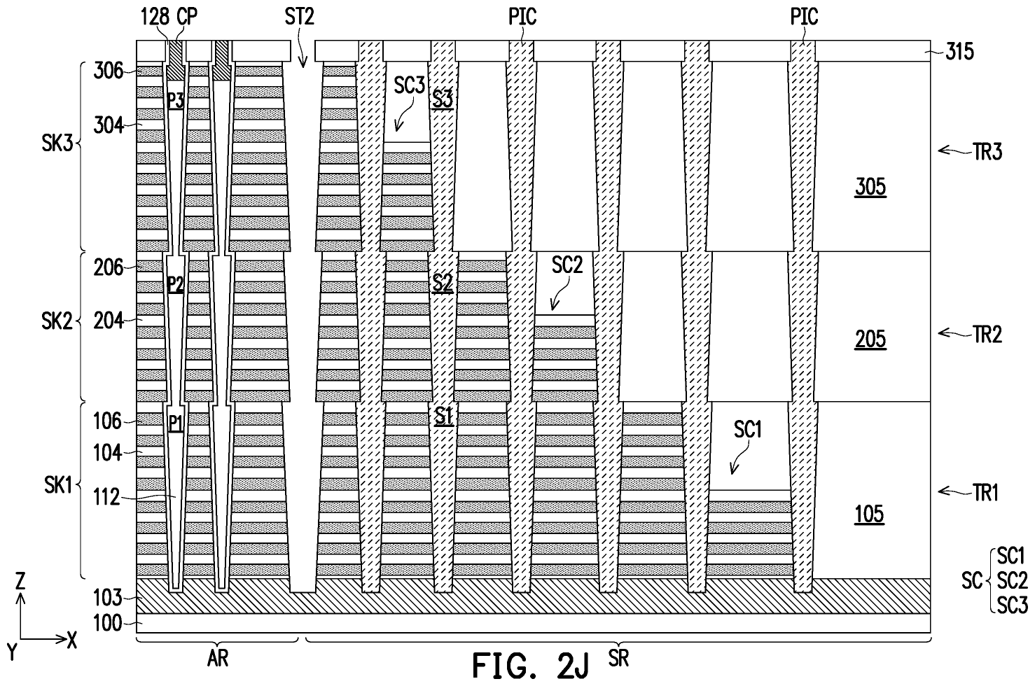

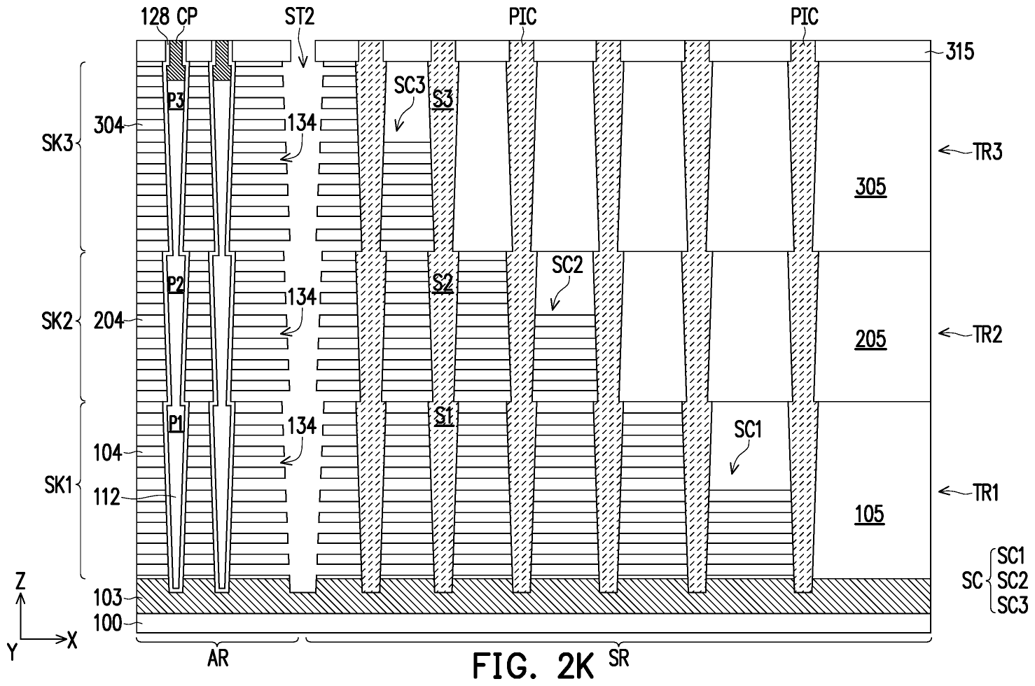

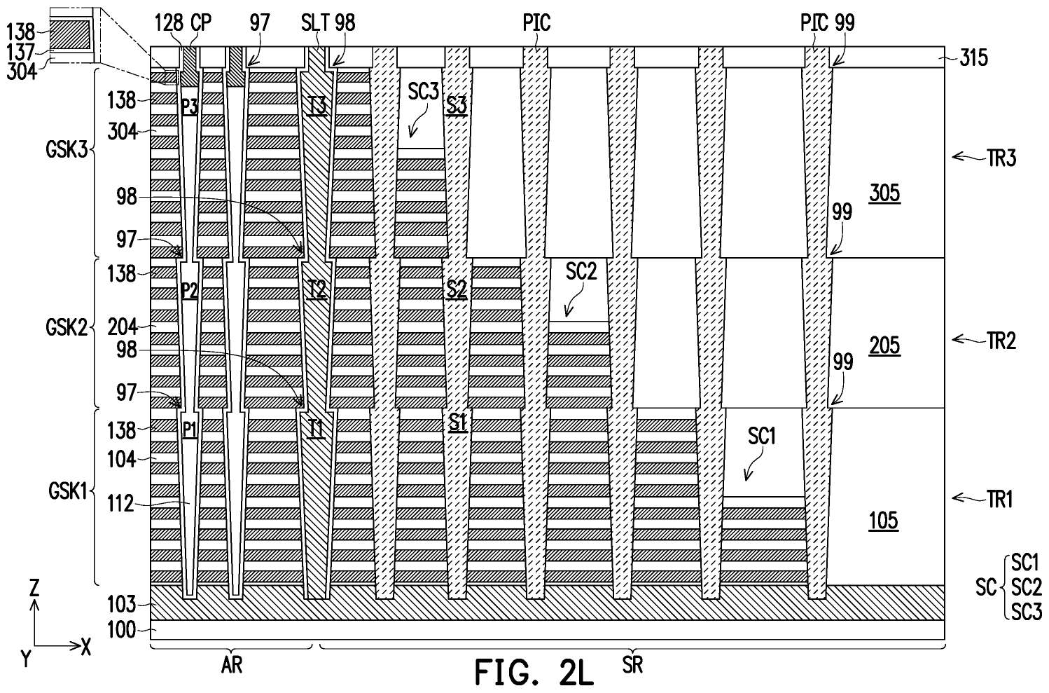

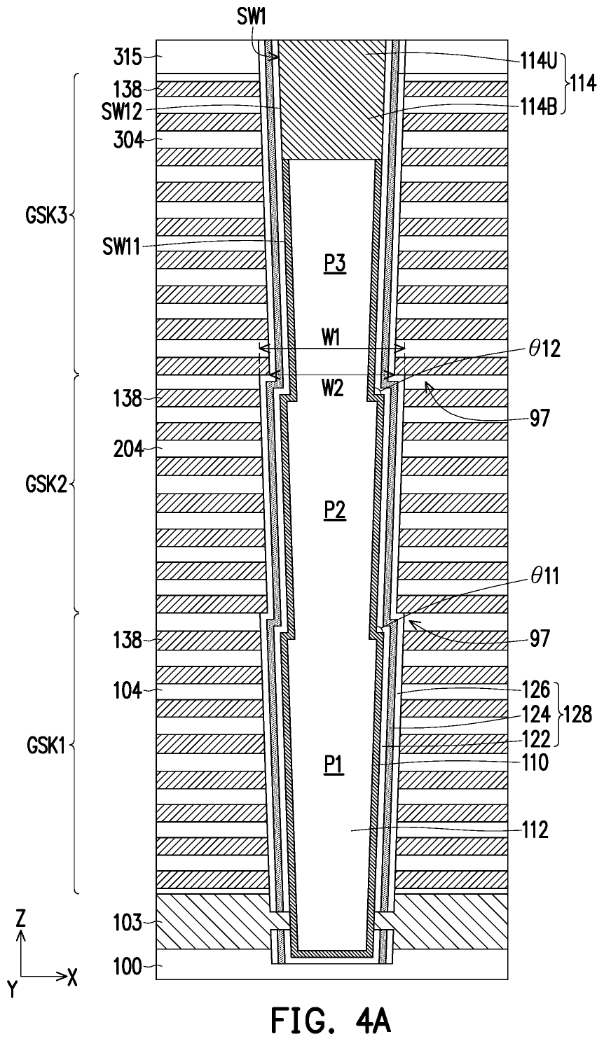

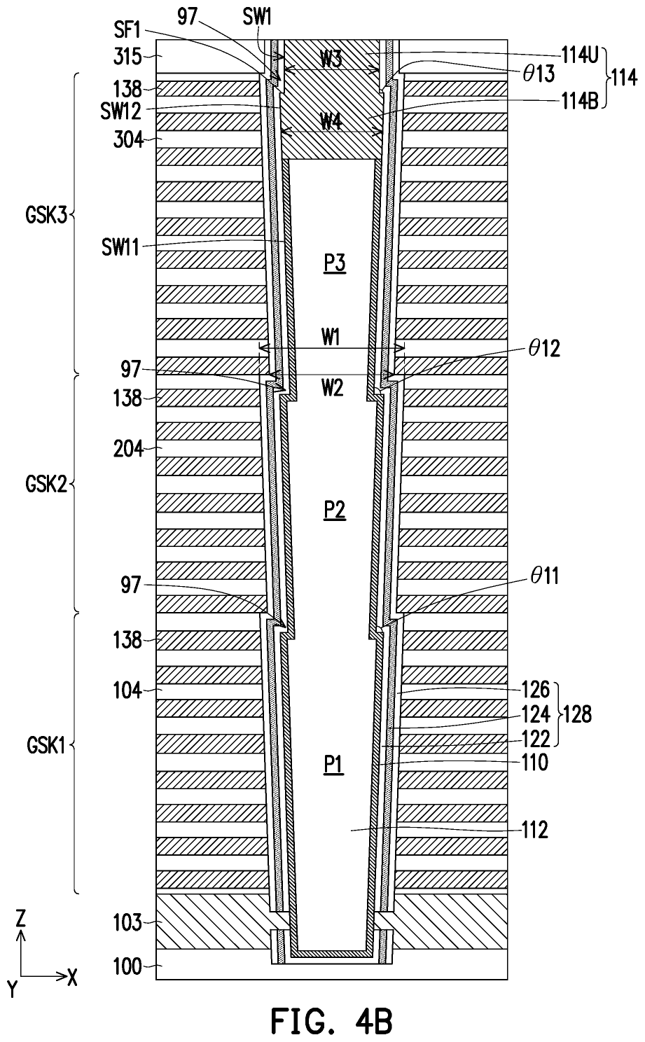

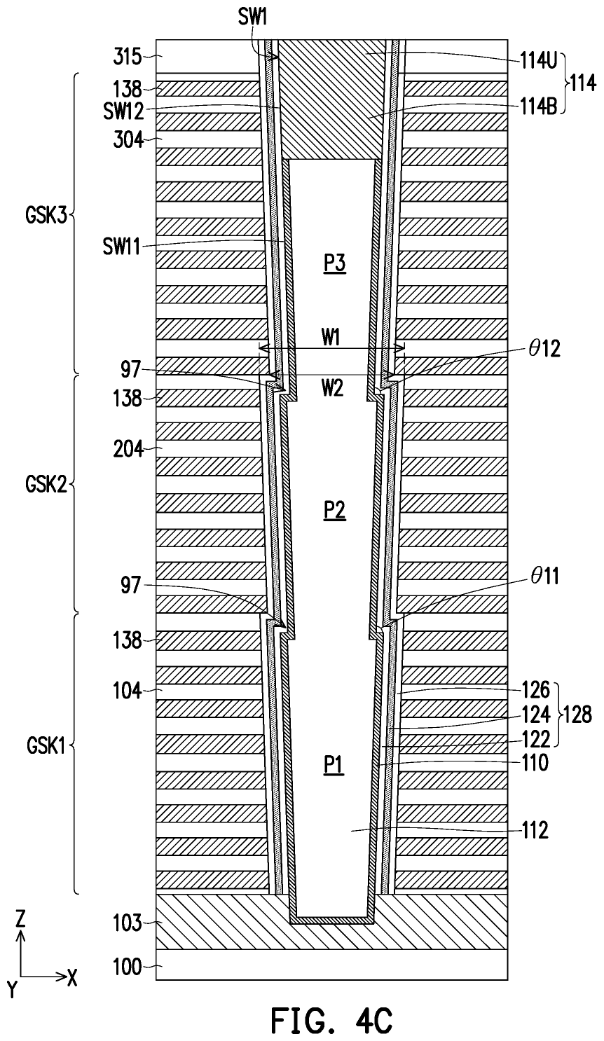

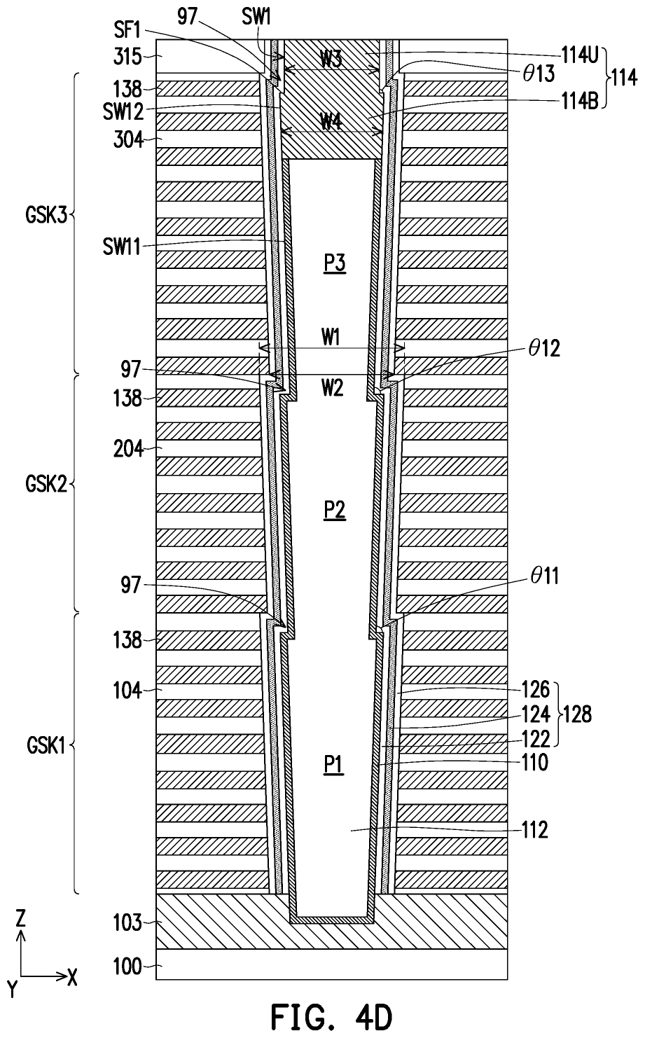

Referring to FIG. 1E, a patterning process, such as photolithography and etching processes, is performed to form a plurality of openings VC′ in the cap insulating layer 315. The openings VC′ expose the sacrificial pillars 360. In some embodiments, the diameter of the opening VC′ may be smaller than the top width of the sacrificial pillar 360. In other embodiments, the diameter of the opening VC′ may be approximately equal to the top width (not shown) of the sacrificial pillar 360. When the diameter of the opening VC′ is smaller than the top width of the sacrificial pillar 360, a sidewall SW12 of a subsequently formed conductive plug 114 has a turn 97, as shown in FIG. 4B and FIG. 4D. When the diameter of the opening VC′ is approximately equal to the top width of the sacrificial pillar 360, a subsequently formed conductive plug 114 has a smooth sidewall SW12, as shown in FIG. 4A and FIG. 4C. FIG. 4A to FIG. 4C respectively show schematic enlarged views of the channel pillars CP in FIG. 1L and FIG. 2L.

Referring to FIG. 1F, the sacrificial pillars 360 exposed by the plurality of openings VC′ and the sacrificial pillars 260 and 160 located below are removed to form a plurality of holes VC. The holes VC extend through the stacked structures SK3, SK2, and SK1. In the embodiments of the disclosure, the profile of the sidewalls of each hole VC is, for example, bamboo-shaped. The method for removing the sacrificial pillars 360, 260, and 160 may be a dry removal method or a wet removal method. When the sacrificial pillars 360, 260, and 160 are carbon-containing organic materials, the sacrificial pillars 360, 260, and 160 may be removed by a dry removal method such as oxygen plasma ashing without issues of over-etching or an insufficient etching depth (open) of the holes VC. When the materials of the sacrificial pillars 360, 260, and 160 are polysilicon or tungsten, the sacrificial pillars 360, 260, and 160 may be removed using a wet removal method.

Referring to FIG. 1G and FIG. 4A to FIG. 4D, a charge storage structure 128 and a channel pillar CP are formed in the hole VC. The charge storage structure 128 may include a tunneling layer 122, a charge storage layer 124, and a blocking layer 126. The tunneling layer 122 is, for example, silicon oxide. The charge storage layer 124 is, for example, silicon nitride. The blocking layer 126 is, for example, silicon oxide or a material with a high dielectric constant equal to or greater than 7, such as aluminum oxide (Al₂O₃), hafnium oxide (HfO₂), lanthanum oxide (La₂O₅), transition metal oxide, lanthanide element oxide, or a combination thereof. In other embodiments, the blocking layer 126 may also be formed in the horizontal opening 134 after the horizontal opening 134 is subsequently formed and before the barrier layer 137 is formed (not shown).

Referring to FIG. 1G and FIG. 4A to FIG. 4D, a channel layer 110 is formed on the charge storage structure 128. In an embodiment, the material of the channel layer 110 includes polysilicon. In an embodiment, the channel layer 110 covers the charge storage structure 128 on the sidewalls of the hole VC, and the channel layer 110 also covers the bottom surface of the hole VC. Subsequently, an insulating pillar 112 is formed at the lower part of the hole VC. In an embodiment, the material of the insulating pillar 112 includes silicon oxide. Afterwards, a conductive plug 114 is formed at the upper part of the hole VC, and the conductive plug 114 is in contact with the channel layer 110. In an embodiment, the material of the conductive plug 114 includes polysilicon. The channel layer 110, the insulating pillar 112, and the conductive plug 114 may be collectively referred to as a channel pillar CP. The charge storage structure 128 surrounds the vertical outer surface of the channel pillar CP.

Referring to FIG. 1H, a plurality of support pillars PIC are formed on the substrate 100. The plurality of support pillars PIC are located in the staircase region SR and pass through the staircase structure SC from the dielectric layer 305, 205, or 105 to the semiconductor layer 103. The support pillar PIC includes an insulating material such as silicon oxide. The method for forming the support pillars PIC includes, for example, forming a plurality of holes in the dielectric layer 305, 205, or 105 and the staircase structure SC by photolithography and etching processes. Next, an insulating material is formed on the cap insulating layer 315 and in the plurality of holes. Afterwards, an etch-back process or a chemical-mechanical planarization process is performed to remove the excess insulating material on the cap insulating layer 315, and the insulating material remaining in the plurality of holes forms the plurality of support pillars PIL.

Referring to FIG. 1I, a patterning process, such as photolithography and etching processes, is performed to form a plurality of trenches ST2′ in the cap insulating layer 315. The trenches ST2′ expose the sacrificial wall 362.

Referring to FIG. 1J, the sacrificial wall 362 exposed by the plurality of trenches ST2′ and the sacrificial walls 262 and 162 located below are removed such that a plurality of slit trenches ST2 are exposed. Referring to both FIG. 1J and FIG. 3, the slit trenches ST2 extend in the direction Y and extend through the stacked structures SK3, SK2, and SK1 along the direction Z. Referring to FIG. 1J, in the embodiments of the disclosure, the profile of the sidewalls of each slit trench ST2 is, for example, bamboo-shaped. The method for removing the sacrificial walls 362, 262, and 162 may be a dry removal method or a wet removal method. When the sacrificial walls 362, 262, and 162 are carbon-containing organic materials, the sacrificial walls 362, 262, and 162 may be removed by a dry removal method such as oxygen plasma ashing without issues of over-etching or an insufficient etching depth (open) of the slit trenches ST2. When the materials of the sacrificial walls 362, 262, and 162 are polysilicon or tungsten, the sacrificial walls 362, 262, and 162 may be removed using a wet removal method.

Since the slit trench ST2 is formed by forming the sacrificial walls 162, 262, and 362 in segments and then removing the sacrificial walls 162, 262, and 362, at this stage, it is not required to further etch the plurality of insulating layers 104, 204, and 304 and the intermediate layers 106, 206, and 306 of the stacked structures SK3, SK2, and SK1. In other words, the slit trench ST2 may be regarded as a self-aligned slit trench. Therefore, it is possible to reduce the difficulty in the fabrication process and avoid damage to the adjacent channel pillars CP caused by etching resulting from improper etching control.

Referring to FIG. 1K, an etching process such as a wet etching process is performed to remove the plurality of intermediate layers 306, 206, and 106 surrounding the slit trench ST2 to thereby form a plurality of horizontal openings 134.

Referring to FIG. 1L, a plurality of gate layers (also referred to as conductive layers) 138 are formed in the plurality of horizontal openings 134. The gate layer 138 is, for example, tungsten (W), molybdenum (Mo), cobalt (Co), or ruthenium (Ru). In some embodiments, before forming the plurality of gate layers 138, a barrier layer 137 is also formed. The material of the barrier layer 137 is, for example, titanium (Ti), titanium nitride (TiN), tantalum (Ta), tantalum nitride (TaN), or a combination thereof. The method for forming the barrier layer 137 and the gate layer 138 includes, for example, sequentially forming a barrier material and a conductive material in the slit trench ST2 and the horizontal openings 134, and then performing an etch-back process to form the barrier layer 137 and the gate layer 138 in the plurality of horizontal openings 134. In other embodiments, a blocking layer 126 may be formed before the barrier layer 137 is formed. The material of the blocking layer 126 is, for example, silicon oxide or a high dielectric constant material with a dielectric constant greater than or equal to 7, such as aluminum oxide (Al₂O₃), hafnium oxide (HfO₂), lanthanum oxide (La₂O₅), transition metal oxides, lanthanide oxides, or combinations thereof.

At this time, stacked structures GSK1, GSK2, and GSK3 have been formed.

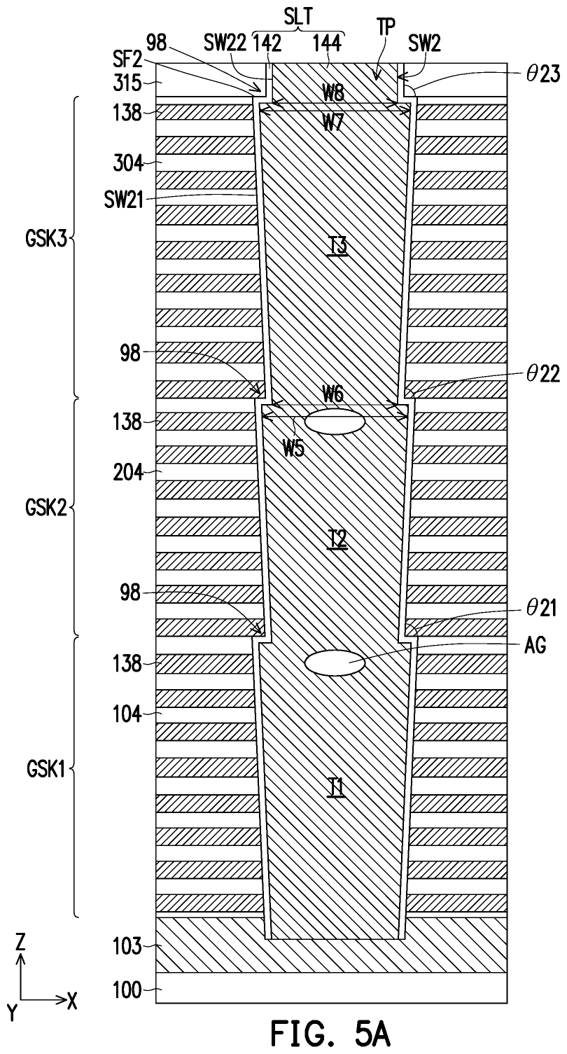

FIG. 5A and FIG. 5B respectively show schematic enlarged views of the separation walls SLT in FIG. 1L and FIG. 2L.

Afterwards, referring to FIG. 1L, FIG. 5A, and FIG. 5B, a separation wall SLT is formed in the slit trench ST2. The separation wall SLT is formed in the slit trench ST2 and is not formed in the hole. The method for forming the separation wall SLT includes filling an insulating liner material and a conductive material on the stacked structure GSK3 and in the slit trench ST2. The insulating liner material is, for example, silicon oxide. The conductive material is, for example, polysilicon, titanium/titanium nitride, tungsten, or a combination thereof. Then, the excess insulating liner material and conductive material on the stacked structure GSK3 are removed by an etch-back process or a planarization process to form a liner layer 142 and a conductive layer 144. The liner layer 142 and the conductive layer 144 are collectively referred to as a separation wall SLT. In some other embodiments, the conductive layer 144 of the separation wall SLT may further encapsulate an air gap AG. In other embodiments, the separation wall SLT may also be completely filled with the insulating material without any conductive layer. In still other embodiments, the separation wall SLT may also be the liner layer 142, and the liner layer 142 encapsulates the air gap AG without any conductive layer.

Afterwards, a contact (not shown) is formed in the staircase region SR. The contact lands at the end of the gate layer 138 in the staircase region SR and is electrically connected thereto.

In the above embodiments, the support pillar PIC is formed after formation of the channel pillar CP. The sidewalls of the support pillar PIC are continuous without turns. In other embodiments, the support pillar PIC may also be formed by first forming a sacrificial pillar and then performing a replacement. FIG. 2A to FIG. 2L are schematic cross-sectional views of a fabrication process of another memory device according to an embodiment of the disclosure.

Referring to FIG. 2A, a semiconductor layer 103, a stacked structure SK1, a staircase structure SC1, and a dielectric layer 105 are formed on a substrate 100 according to the above method. Then, when forming sacrificial pillars 160 and a sacrificial wall 162, sacrificial pillars 163 are also formed. The sacrificial pillars 163 pass through the stacked structure SK1 in the staircase region SR, the staircase structure SC1, the dielectric layer 105 to the semiconductor layer 103. The sacrificial pillar 163 has a circular profile (not shown). In some embodiments, the upper width of the plurality of sacrificial pillars 163 is greater than the lower width thereof, and the cross-section of the sacrificial pillar 163 has, for example, a conical shape. The sacrificial pillar 160, the sacrificial wall 162, and the sacrificial pillar 163 are, for example, amorphous silicon or carbon-containing organic materials. The carbon-containing organic material may be a polymer such as a photoresist. The photoresist may be a positive photoresist or a negative photoresist. At this time, a first tier TR1 has been formed.

In the fabrication process, by controlling the number of layers, the photolithography, and the etching process of the intermediate layers 106 and the insulating layers 104 of the stacked structure SK1, the opening for forming the sacrificial pillar 163 may have the required profile and shape, and a sufficient distance may be provided between the opening for forming the sacrificial pillar 163 and the slit trench ST1. Thus, it is possible to avoid the difficulty in control of the etching plasma resulting from an excessive depth, which may otherwise cause the slit trench to tilt or shift, cause formation of a notch in the opening of the sacrificial pillar 163, and lead to abnormal communication between the opening of the sacrificial pillar 163 and the slit trench ST1.

Referring to FIG. 2B, a second tier TR2 and a third tier TR3 are formed according to the above method. When forming sacrificial pillars 260, a sacrificial wall 262, sacrificial pillars 360, and a sacrificial wall 362 of the second tier TR2 and the third tier TR3, a plurality of sacrificial pillars 263 and 363 are also formed at the same time, respectively. The sacrificial pillar 263 lands on the sacrificial pillar 163, and the sacrificial pillar 363 lands on the sacrificial pillar 263. In this embodiment, the profiles of the sacrificial pillars 163, 263, and 363 are, for example, bamboo-shaped. Afterwards, a cap insulating layer 315 is formed on the stacked structure SK3. At this time, the stacked structures SK1, SK2, and SK3 composed of the insulating layers 104, 204, and 304 and the intermediate layers 106, 206, and 306 have been formed, the dielectric layers 105, 205, and 305 have been formed around the stacked structures SK1, SK2, and SK3, and the cap insulating layer 315 is covered on the stacked structure SK3. In other embodiments, the stacked structures SK1, SK2, and SK3, the dielectric layers 105, 205, and 305 and the cap insulating layer 315 may also be formed using any known methods.

Referring to FIG. 2C, a patterning process, such as photolithography and etching processes, is performed to form a plurality of holes OP2′ in the cap insulating layer 315. The holes OP2′ expose the sacrificial pillars 363.

Referring to FIG. 2D, the sacrificial pillars 363 exposed by the plurality of holes OP2′ and the sacrificial pillars 263 and 163 located below are removed such that a plurality of holes OP2 are exposed. The holes OP2 extend through the stacked structures SK3, SK2, and SK1. The method for removing the sacrificial pillars 363, 263, and 163 may be a dry removal method or a wet removal method. When the sacrificial pillars 363, 263, and 163 are carbon-containing organic materials, the sacrificial pillars 363, 263, and 163 may be removed by a dry removal method such as oxygen plasma ashing without issues of over-etching or an insufficient etching depth (open) of the holes OP2. In the embodiments of the disclosure, the profile of the sidewalls of each hole OP2 is, for example, bamboo-shaped.

Referring to FIG. 2E, a plurality of support pillars PIC are formed in the holes OP2. The support pillar PIC includes an insulating material such as silicon oxide. The method for forming the support pillars PIC includes, for example, forming an insulating material on the cap insulating layer 315 and in the plurality of holes. Afterwards, an etch-back process or a chemical-mechanical planarization process is performed to remove the excess insulating material on the cap insulating layer 315, and the insulating material remaining in the plurality of holes forms a plurality of support pillars PIL. As can be learned from FIG. 3, the profile of the support pillar PIC is circular.

Referring to FIG. 2F to FIG. 2H, according to the method described with reference to FIG. 1E to FIG. 1G above, a patterning process is performed to form a plurality of openings VC′ in the cap insulating layer 315, as shown in FIG. 2F. Then, the sacrificial pillars 360, 260, and 160 are removed to form a plurality of holes VC, as shown in FIG. 2G. Afterwards, a charge storage structure 128 and a channel pillar CP are formed in the hole VC, as shown in FIG. 2H and FIG. 4A to FIG. 4D.

Referring to FIG. 2I to FIG. 2L, according to the method described with reference to FIG. 1I to FIG. 1L above, a patterning process is performed to form a plurality of trenches ST2′ in the cap insulating layer 315, as shown in FIG. 2I. The sacrificial wall 362 exposed by the plurality of trenches ST2′ and the sacrificial walls 262 and 162 located below are removed to expose a plurality of slit trenches ST2, as shown in FIG. 2J. An etching process such as a wet etching process is performed to remove the plurality of intermediate layers 306, 206, and 106 surrounding the slit trench ST2 to form horizontal openings 134, as shown in FIG. 2K. Afterwards, a barrier layer 137 and a gate layer 138 are formed in the horizontal opening 134, as shown in FIG. 2L.

Referring to FIG. 2L, FIG. 5A, and FIG. 5B, a separation wall SLT is formed in the slit trench ST2. Afterwards, a contact (not shown) is formed in the staircase region SR. The contact lands at the end of the gate layer 138 in the staircase region SR and is electrically connected thereto.

Referring to FIG. 4A to FIG. 4D, in the embodiment of the disclosure, the channel pillar CP includes a plurality of portions P1, P2, and P3 stacked on each other. Two adjacent portions, e.g., the portions P1 and P2, of the channel pillar CP are connected with each other in the vicinity of a boundary between the gate stack structures GSK1 and GSK2, or two adjacent portions, e.g., the portions P2 and P3, of the channel pillar CP are connected with each other in the vicinity of a boundary between the gate stack structures GSK2 and GSK3. Of two adjacent portions (e.g., the portions P3 and P2) of the channel pillar CP, an upper width (i.e., an upper radial dimension) W1 of the lower portion (e.g., the portion P2) is greater than a lower width (i.e., a lower radial dimension) W2 of the upper portion (e.g., the portion P3). A sidewall SW1 of the channel pillar CP is not smooth, but has turns 97 at connections between the portions. In FIG. 4A to FIG. 4D, the turn 97 formed between the top surface of an upper part of the portion P1 and the sidewall of a lower part of the portion P2 has an included angle θ11. The turn 97 formed between the top surface of an upper part of the portion P2 and the sidewall of a lower part of the portion P3 has an included angle θ12. The included angles θ11 and 012 are less than 90 degrees.

The channel layer 110 and the conductive plug 114 in the channel pillar CP are formed by a deposition process, so the channel layer 110 and the conductive plug 114 continuously extend from the top surface of the gate stack structure GSK3 to the bottom surface of the gate stack structure GSK1, and a planarization interface is not present between the portions P3 and P2 or between the portions P2 and P1.

Furthermore, in some embodiments, the sidewall of the channel layer 110 of the channel pillar CP may be electrically connected to the semiconductor layer 103, as shown in FIG. 4A and FIG. 4B. In other embodiments, the lower sidewall and the bottom surface of the channel layer 110 of the channel pillar CP may be electrically connected to the semiconductor layer 103, as shown in FIG. 4C and FIG. 4D.

Referring to FIG. 4A and FIG. 4C, the width range from the top width to the bottom width of the channel pillar CP is, for example, 130 nm to 80 nm. A sidewall SW12 of the conductive plug 114 is connected to a sidewall SW11 of the portion P3. An upper part 114U and a lower part 114B of the conductive plug 114 have approximately the same dimensions. A sidewall SW12 of the conductive plug 114 is smooth and does not have a turn 97 at the connection between the upper part 114U and the lower part 114B. Referring to FIG. 4B and FIG. 4D, the conductive plug 114 includes an upper part 114U and a lower part 114B. A width W3 of the upper part 114U is smaller than a width W4 of the lower part 114B. A sidewall SW12 of the conductive plug 114 is not smooth, but has a turn 97 at the connection between the upper part 114U and the lower part 114B. The turn 97 formed between the sidewall of the upper part 114U and a top surface SF1 of the lower part 114B has an included angle θ13. The included angle θ13 is less than 90 degrees.

Referring to FIG. 5A, FIG. 5B, and FIG. 3, in the embodiment of the disclosure, the separation wall SLT includes a plurality of sub-walls T1, T2, and T3 stacked on each other along the direction Z. The sub-walls T1, T2, and T3 respectively extend along the direction Y, extend from the array region AR to the staircase region SR, and thus have strip shapes in the top view of FIG. 3. The sub-walls T1, T2, and T3 are sequentially buried in the stacked structures GSK1, GSK2, and GSK3. Two adjacent sub-walls of the separation wall SLT are connected with each other. For example, the sub-walls T1 and T2 are connected with each other in the vicinity of a boundary between the gate stack structures GSK1 and GSK2, or the sub-walls T2 and T3 are connected with each other in the vicinity of a boundary between the gate stack structures GSK2 and GSK3. Of two adjacent sub-walls (e.g., the sub-walls T3 and T2) of the separation wall SLT, an upper width W5 of the lower sub-wall (e.g., the sub-wall T2) is greater than a lower width W6 of the upper sub-wall (e.g., the sub-wall T3). The maximum width (e.g., the upper width W5 of the sub-wall T2) of the separation wall SLT is smaller than 400 nm. The minimum width (e.g., the lower width W6 of the sub-wall T3) of the separation wall SLT is greater than 80 nm.

A sidewall SW3 of the separation wall SLT is not smooth, but has turns 98 at the connections between the sub-walls.

In FIG. 5A and FIG. 5B, the turn 98 formed between the top surface of an upper part of the sub-wall T1 and the sidewall of a lower part of the sub-wall T2 has an included angle θ21. The turn 98 formed between the top surface of an upper part of the sub-wall T2 and the sidewall of a lower part of the sub-wall T3 has an included angle θ22. The included angles θ21 and 022 are less than 90 degrees.

The liner layer 142 and the conductive layer 144 in the separation wall SLT are formed by a deposition process, so the liner layer 142 and the conductive layer 144 continuously extend from the top surface of the stacked structure GSK3 to the bottom surface of the stacked structure GSK1 (shown in FIG. 1L), and a planarization interface is not present between the sub-walls T3 and T2 or between the sub-walls T2 and T1.

FIG. 5A and FIG. 5B respectively show schematic enlarged views of the separation walls SLT in FIG. 1L and FIG. 2L.

Referring to FIG. 5A and FIG. 5B, the separation wall SLT further includes a cap part TP. The cap part TP is buried in the cap insulating layer 315 and is located on the sub-wall T3. Referring to FIG. 5A, a width W8 of the cap part TP is smaller than an upper width W7 of the adjacent sub-wall T3. A sidewall SW22 of the cap part TP and a sidewall SW21 of the sub-wall T3 are connected to each other via the top surface SF1 of the sub-wall T3.

Referring to FIG. 5B, the width W8 of the cap part TP may also be approximately equal to the upper width W7 of the adjacent sub-wall T3. The sidewall SW22 of the cap part TP is connected with the sidewall SW21 of the sub-wall T3. The cap part TP may have a vertical sidewall SW4 or an inclined sidewall. In FIG. 5A, the turn 98 formed between a top surface SF2 of an upper part of the sub-wall T3 and the sidewall SW22 of the cap insulating layer 315 has an included angle θ23. The included angles θ21, θ22, and θ23 are less than 90 degrees.

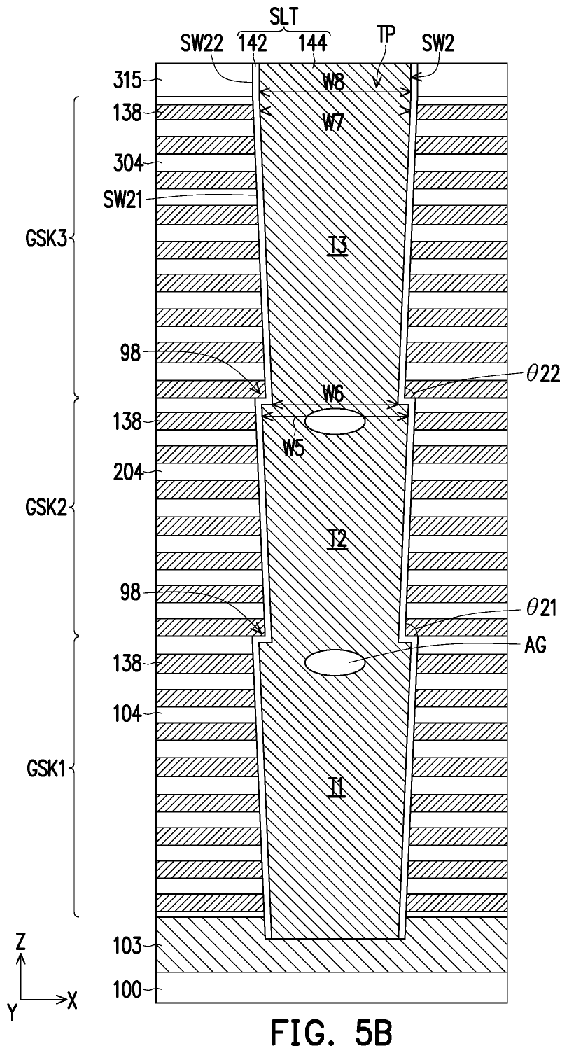

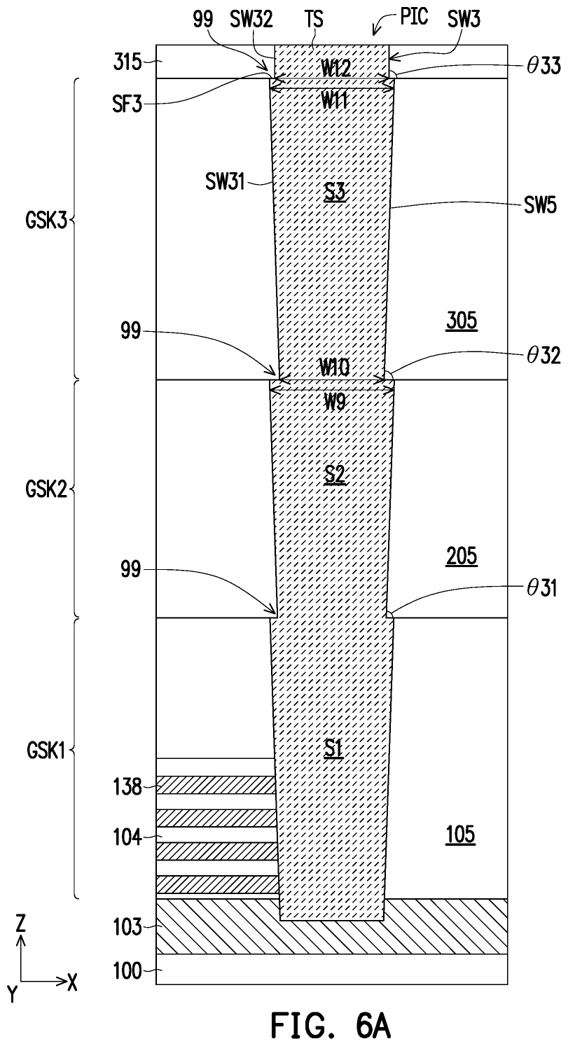

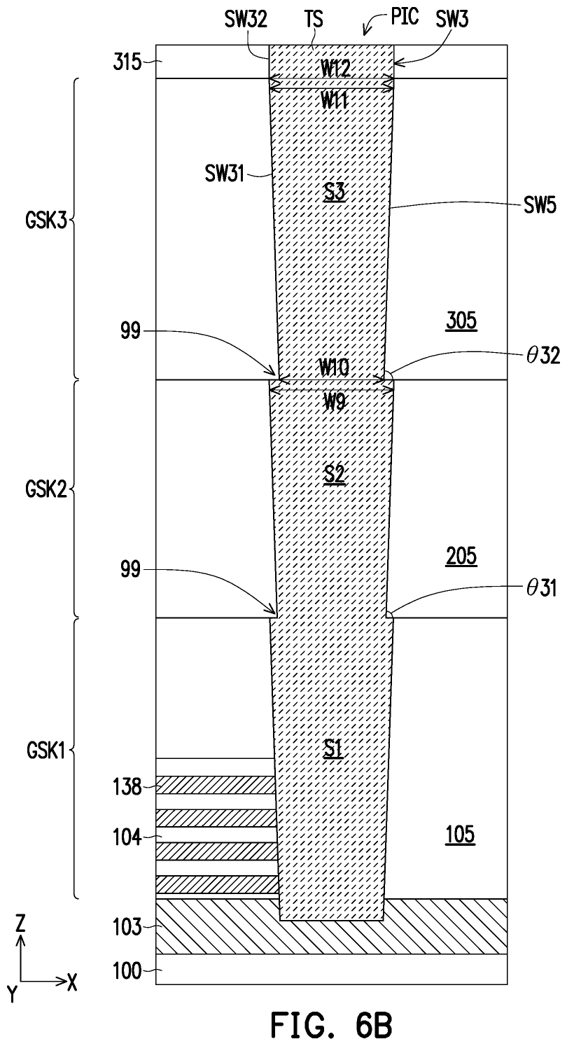

FIG. 6A and FIG. 6B respectively show schematic enlarged views of the support pillar PIC in FIG. 2L.

Referring to FIG. 6A and FIG. 6B, in the embodiment of the disclosure, the support pillar PIC includes a plurality of sub-pillars S1, S2, and S3 stacked on each other and respectively buried in the staircase structures SC1, SC2, and SC3 and the dielectric layers 105, 205, and 305 of the stacked structures GSK1, GSK2, and GSK3. Of two adjacent sub-pillars (e.g., the sub-pillars S3 and S2) of the support pillar PIL, an upper width (i.e., an upper radial dimension) W9 of the lower sub-pillar (e.g., the sub-pillar S2) is greater than a lower width (i.e., a lower radial dimension) W10 of the upper sub-pillar (e.g., the sub-pillar S3). A sidewall SW3 of the support pillar PIC is not smooth, but has turns 99 at the connections between the sub-pillars.

In FIG. 6A and FIG. 6B, the turn 99 formed between the top surface of an upper part of the sub-pillar S1 and the sidewall of a lower part of the sub-pillar S2 has an included angle θ31. The turn 99 formed between the top surface of an upper part of the sub-pillar S2 and the sidewall of a lower part of the sub-pillar S3 has an included angle θ32. The included angles θ31 and θ32 are less than 90 degrees.

The material of the support pillar PIC is formed by a deposition process after formation of the hole OP2, so the support pillar PIC continuously extends from the top surface of the stacked structure GSK3 to the bottom surface of the stacked structure GSK1 (shown in FIG. 1L), and a planarization interface is not present between the sub-pillars S3 and S2 or between the sub-pillars S2 and S1.

Referring to FIG. 6A and FIG. 6B, the support pillar PIC further includes a cap part TS. The cap part TS is buried in the cap insulating layer 315 and is located on the sub-pillar S3. Referring to FIG. 6A, a width W12 of the cap part TS is smaller than an upper width W11 of the adjacent sub-pillar S3. A sidewall SW32 of the cap part TS and a sidewall SW31 of the sub-pillar S3 are connected to each other via a top surface SF3 of the sub-pillar S3.

Referring to FIG. 6B, the width W12 of the cap part TS may also be approximately equal to the upper width W11 of the adjacent sub-pillar S3. The sidewall SW32 of the cap part TS is connected with the sidewall SW31 of the sub-pillar S3. The cap part TS may have a vertical sidewall SW6 or an inclined sidewall (not shown). In FIG. 6A, the turn 99 formed between the top surface of an upper part of the sub-pillar S3 and the sidewall of the cap insulating layer 315 has an included angle θ33. The included angle θ33 is less than 90 degrees.

Referring to FIG. 2L, the turns 97, 98, and 99 located at the boundary between the stacked structures GSK1 and GSK2 have substantially the same height. The turns 97, 98, and 99 located at the boundary between the stacked structures GSK2 and GSK3 have substantially the same height. The turns 97, 98, 99 located at the boundary between the stacked structure GSK3 and the cap insulating layer 315 have substantially the same height.

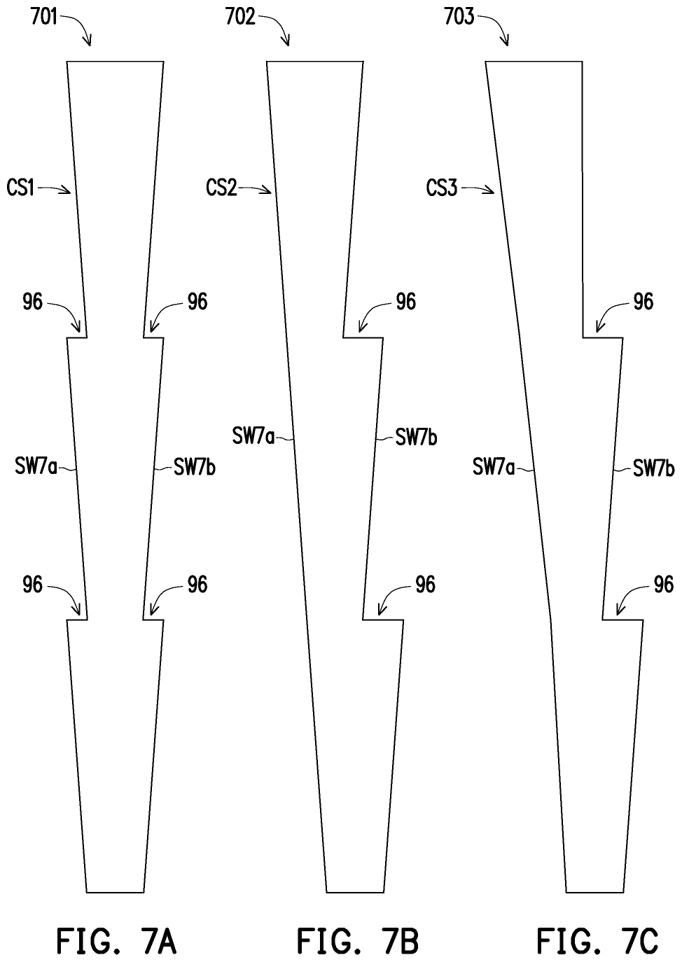

Referring to FIG. 4A to FIG. 6B, in the above embodiments, the profiles of the channel pillar CP, the separation wall SLT, and the support pillar PIC (collectively referred to as a combined structure CS1) in the gate stack structures GSK1, GSK2, and GSK3 are shown as a profile 701 in FIG. 7A. However, the embodiments of the disclosure are not limited thereto. In some cases, the profiles of the channel pillar CP, the separation wall SLT, and the support pillar PIC (collectively referred to as combined structures CS2 and CS3) in the gate stack structures GSK1, GSK2, and GSK3 are shown as a profile 702 in FIG. 7B and a profile 703 in FIG. 7C.

Referring to FIG. 7A to FIG. 7C, the combined structure CS1 is a symmetrical structure, and the combined structures CS2 and CS3 are asymmetrical structures. The numbers of turns 96 are equal on two sidewalls of the combined structure CS1, and the numbers of turns 96 are different on two sidewalls SW7a and SW7b of the combined structures CS2 and CS3. In the combined structure CS2, only one sidewall SW7b has obvious turns 96, and the other sidewall SW7a does not have a turn 96 and is smooth. In the combined structure CS3, only one sidewall SW7b has obvious turns 96, and the other sidewall SW7a is not smooth. In other embodiments, the two sidewalls SW7a and SW7b of the combined structure CS2 both have obvious turns 96, but the numbers of turns 96 are different on the two sidewalls (not shown).

The above embodiments have been described with three stacked structures, but the disclosure may be applied to memory devices with more stacked structures. Furthermore, the stacked structure (with a memory array) of the disclosure may have complementary metal-oxide-semiconductor devices provided below the stacked structure. In some embodiments, these complementary metal-oxide-semiconductor devices may be formed before formation of the stacked structure and are thus located below the memory array. This type is also known as a complementary metal-oxide-semiconductor under array (CMOS under Array, CuA) structure. In other embodiments, these complementary metal-oxide-semiconductor devices may be formed below the memory array by bonding. This type is also known as a complementary metal-oxide-semiconductor bonding array (CMOS bonding array, CbA) structure.

The above embodiments have been described with a charge storage structure having a charge trapping structure. However, the embodiments of the disclosure may also be applied to a floating gate memory. In addition, the above embodiments have been described with a 3D NAND flash memory. However, the embodiments of the disclosure are not limited thereto, and the embodiments of the disclosure may also be applied to a 3D NOR flash memory or a 3D AND flash memory.

Based on the above, in the memory device according to the embodiments of the disclosure, the stacked structure is formed as a plurality of divided portions, which can reduce the aspect ratio of the holes or trenches formed in the stacked structure to thereby reduce the difficulty in the fabrication process and reduce the fabrication costs. In addition, the disclosure also forms sacrificial pillars or sacrificial walls in holes or trenches formed in advance. After formation of holes or openings located above, these sacrificial pillars or sacrificial walls can be easily removed to form holes or slit trenches that extend through the stacked structure and have a high aspect ratio. Therefore, the disclosure can simplify the fabrication process, integrate with existing processes, increase integration, increase the process yield, and reduce the fabrication costs.

What is claimed is:

1. A memory device comprising:
a stacked structure located above a substrate and comprising a plurality of conductive layers and a plurality of insulating layers arranged alternately with each other;
a channel pillar passing through the stacked structure;
a charge storage structure located between the channel pillar and the conductive layer; and
a separation wall passing through the stacked structure, the separation wall comprising a plurality of sub-walls stacked on each other, wherein
of two adjacent sub-walls among the plurality of sub-walls of the separation wall, an upper width of a lower sub-wall is greater than a lower width of an upper sub-wall.

2. The memory device according to claim 1, wherein at least one of a plurality of sidewalls of the separation wall has at least one first turn.

3. The memory device according to claim 1, wherein each of sidewalls of the separation wall has a same number of first turns.

4. The memory device according to claim 1, wherein sidewalls of the separation wall have different numbers of first turns from each other.

5. The memory device according to claim 1, wherein the separation wall further comprises a cap part, and a width of the cap part is smaller than an upper width of the sub-wall adjacent to the cap part.

6. The memory device according to claim 1, wherein the channel pillar comprises a plurality of portions stacked on each other.

7. The memory device according to claim 6, wherein, of two adjacent portions among the plurality of portions of the channel pillar, an upper width of a lower portion is greater than a lower width of an upper portion.

8. The memory device according to claim 7, wherein at least one of a plurality of sidewalls of the channel pillar has at least one second turn.

9. The memory device according to claim 1, further comprising a support pillar that passes through a staircase structure of the stacked structure and a dielectric layer covering the staircase structure, wherein the support pillar comprises a plurality of sub-pillars stacked on each other.

10. The memory device according to claim 9, wherein, of two adjacent sub-pillars among the plurality of sub-pillars of the support pillar, an upper width of a lower sub-pillar is greater than a lower width of an upper sub-pillar.

11. The memory device according to claim 10, wherein at least one of a plurality of sidewalls of the support pillar has at least one third turn.

12. A memory device comprising:
a staircase structure located above a substrate and comprising a plurality of conductive layers and a plurality of insulating layers arranged alternately with each other;
a dielectric layer covered on the staircase structure;
a support pillar passing through the staircase structure and the dielectric layer, wherein the support pillar comprises a plurality of sub-pillars stacked on each other, wherein
of two adjacent sub-pillars among the plurality of sub-pillars of the support pillar, an upper width of a lower sub-pillar is greater than a lower width of an upper sub-pillar.

13. The memory device according to claim 12, wherein at least one of sidewalls of the support pillar has at least one turn.

14. The memory device according to claim 13, wherein each of sidewalls of the support pillar has a same number of turns.

15. The memory device according to claim 13, wherein sidewalls of the support pillar have different numbers of turns from each other.

16. The memory device according to claim 12, wherein the support pillar further comprises a cap part, and a width of the cap part is smaller than an upper width of the sub-pillar adjacent to the cap part.

17. A method of fabricating a memory device, comprising:
forming a stacked structure located above a substrate, the stacked structure comprising a plurality of conductive layers and a plurality of insulating layers arranged alternately with each other;
forming a channel pillar in the stacked structure;
forming a charge storage structure between the channel pillar and the conductive layer;
forming a separation wall passing through the stacked structure, the separation wall comprising a plurality of sub-walls stacked on each other, wherein, of two adjacent sub-walls among the plurality of sub-walls of the separation wall, an upper width of a lower sub-wall is greater than a lower width of an upper sub-wall; and
forming a support pillar passing through a staircase structure of the stacked structure and a dielectric layer on the staircase structure, wherein the support pillar comprises a plurality of sub-pillars stacked on each other, wherein, of two adjacent sub-pillars among the plurality of sub-pillars of the support pillar, an upper width of a lower sub-pillar is greater than a lower width of an upper sub-pillar.

18. The method of fabricating a memory device according to claim 17, wherein at least one of sidewalls of the separation wall has at least one first turn.

19. The method of fabricating a memory device according to claim 18, wherein at least one of sidewalls of the support pillar has at least one second turn.

20. The method of fabricating a memory device according to claim 19, wherein the at least one first turn and the at least one second turn have a same height.
